(19) United States
(12) Patent Application Publication
(10) Pub. No.: US 2012/0217577 A1
(43) Pub. Date: Aug. 30, 2012

(54) SEMICONDUCTOR DEVICE

(75) Inventors: Takayuki HASHIMOTO, Tokai (JP); Masahiro Masunaga, Hitachi (JP)

(73) Assignee: RENESAS ELECTRONICS CORPORATION

(21) Appl. No.: 13/402,973

(22) Filed: Feb. 23, 2012

(30) Foreign Application Priority Data
Feb. 25, 2011 (JP) 2011-039295

(51) Int. Cl. H01L 29/78

(52) U.S. Cl. 257/330; 257/E29.262

(57) ABSTRACT

A trench-gate vertical-channel type power MOSFET has an advantage of a low on-state resistance. With increasing miniaturization, fluctuations in on-state resistance have posed a problem. In addition, a structural limitation in miniaturization also has posed a problem. These problems are not only those of a single power MOSFET but also are important ones in integrated circuit devices, such as IGBT using a similar structure, obtained by integrating CMOS and such a power active device on a single chip. The invention provides a semiconductor device having a trench-gate vertical-channel type power active device, such as trench-gate vertical-channel type power MOSFET, in which the width of the interlayer insulating film is made almost equal to that of the trench and a portion of the source region is comprised of a polysilicon member.

### CROSS-REFERENCE TO RELATED APPLICATIONS

The disclosure of Japanese Patent Application No. 2011-39295 filed on Feb. 25, 2011 including the specification, drawings and abstract is incorporated herein by reference in its entirety.

### BACKGROUND

The present invention relates to a technology effective when applied to the device structure of a semiconductor device (or a semiconductor integrated circuit device) such as power MOSFET (metal oxide semiconductor field effect transistor) or MISFET (metal insulator semiconductor field effect transistor).

U.S. Pat. No. 6,916,745 (Patent Document 1) discloses a trench-gate type vertical-channel power MOSEFT and the like in which an interlayer insulating film electrically separating between a gate electrode and a source electrode lying thereover has a width greater than that of the gate electrode.

Japanese Patent Laid-Open No. 2002-158233 (Patent Document 2), Japanese Patent Laid-Open No. 2002-158352 (Patent Document 3), and Japanese Patent Laid-Open No. 2002-158354 (Patent Document 4) disclose a technology for reducing the on-state resistance of a trench-gate type vertical-channel power MOSFET by using a poly Si sidewall, which is provided in an interlayer insulating film, as a portion of a source region together with a source region in a semiconductor substrate (which will hereinafter be called “in-substrate source region”), which is provided in the surface of the substrate.

Kenya Kobayashi and three others, “Sub-micron Cell Pitch 30V N-channel UMOSFET with Ultra Low On-state resistance”, Proceedings of the 19th International Symposium on Power Semiconductor Devices & ICs, May 27-30, 2007 Jeju, Korea (Non-patent Document 1) discloses, as a structure having a reduced on-state resistance, a buried interlayer insulating-film type trench-gate type vertical-channel power MOSEFT and the like in which the upper surface of a semiconductor substrate in an active cell region and the upper surface of an interlayer insulating film are on substantially the same level; and the width of a trench is almost equal to that of the interlayer insulating film.
[Patent Document 1] U.S. Pat. No. 6,916,745
[Patent Document 2] Japanese Patent Laid-Open No. 2002-158233
[Patent Document 3] Japanese Patent Laid-Open No. 2002-158352
[Patent Document 4] Japanese Patent Laid-Open No. 2002-158354
[Non-patent Document 1]
Kenya Kobayashi and three others, “Sub-micron Cell Pitch 30V N-channel UMOSFET with Ultra Low On-state resistance”, Proceedings of the 19th International Symposium on Power Semiconductor Devices & ICs, May 27-30, 2007 Jeju, Korea

### SUMMARY

Trench-gate vertical-channel type power MOSFET and the like have an advantage of a low on-state resistance. With recent advancements in miniaturization, however, fluctuations in on-state resistance have posed a problem. In addition, the limits of miniaturization have posed a problem from the structural standpoint. These problems are not only those for a power MOSFET or IGBT (insulated gate bipolar transistor) having a similar structure but also important problems for integrated circuit devices, a so-called Dr. MOS, in which a CMOS (complementary metal oxide semiconductor) or the like and a power active element thereof have been integrated on a single chip.

The present invention has been made with a view to overcoming these problems.

An object of the invention is to provide a semiconductor device having high reliability.

The above-described object and other objects, and novel features of the invention will be apparent from the description herein and accompanying drawings.

Of the inventions disclosed herein, the summary of the typical invention will next be described briefly.

One of the inventions according to the present application is a semiconductor device having a trench-gate vertical-channel power active element such as trench-gate vertical-channel power MOSFET, in which an interlayer insulating film and a trench are adjusted to have a substantially equal width and a source region is composed partially of a polysilicon member.

An advantage available from a typical invention, among the inventions disclosed herein, will next be described briefly.

In a semiconductor device having a trench-gate vertical-channel type power active element such as trench-gate vertical-channel type power MOSFET, an interlayer insulating film and a trench are formed with a substantially equal width and at the same time, a portion of a source region is made of a polysilicon member so that miniaturization of the device can be achieved more easily.

### BRIEF DESCRIPTION OF THE DRAWINGS

FIG. 1 is a schematic circuit diagram showing the circuit configuration of a DC-DC converter for computer which is a main application field of a semiconductor device of each embodiment of the present application;

FIG. 2 is an overall top view of a semiconductor chip of a power MOSFET which is one example of the semiconductor device of each embodiment of the present application;

FIG. 3 is a schematic cross-sectional view of the chip corresponding to the X-X′ cross-section of FIG. 2;

FIG. 4 is an enlarged top view of the cutout region R1 of the gate electrode lead-out portion of FIG. 2;

FIG. 5 is a detailed cross-sectional view of the unit cell region 20 of FIG. 3, that is, an active cell structure (basic structure of cell) of a power MOSFET which is one example of the semiconductor device according to one embodiment of the present application;

FIG. 6 is a cross-sectional view of the unit cell region corresponding to FIG. 5 (basic structure of cell) during a manufacturing step (trench formation step);

FIG. 7 is a cross-sectional view of the unit cell region corresponding to FIG. 5 (basic structure of cell) during a manufacturing step (gate oxidation step);

FIG. 8 is a cross-sectional view of the unit cell region corresponding to FIG. 5 (basic structure of cell) during a manufacturing step (gate polysilicon burying step);

FIG. 9 is across-sectional view of the unit cell region corresponding to FIG. 5 (basic structure of cell) during a manufacturing step (gate polysilicon etch-back step);

FIG. 10 is a cross-sectional view of the unit cell region corresponding to FIG. 5 (basic structure of cell) during a manufacturing step (interlayer insulating film burying step);

FIG. 11 is a cross-sectional view of the unit cell region corresponding to FIG. 5 (basic structure of cell) during a manufacturing step (planarization step);

FIG. 12 is a cross-sectional view of the unit cell region corresponding to FIG. 5 (basic structure of cell) during a manufacturing step (substrate etching step);

FIG. 13 is a cross-sectional view of the unit cell region corresponding to FIG. 5 (basic structure of cell) during a manufacturing step (P-type body region introduction step);

FIG. 14 is a cross-sectional view of the unit cell region corresponding to FIG. 5 (basic structure of cell) during a manufacturing step (sidewall polysilicon film formation step);

FIG. 15 is a cross-sectional view of the unit cell region corresponding to FIG. 5 (basic structure of cell) during a manufacturing step (sidewall formation step);

FIG. 16 is a cross-sectional view of the unit cell region corresponding to FIG. 5 (basic structure of cell) during a manufacturing step (source impurity introduction step);

FIG. 17 is a cross-sectional view of the unit cell region corresponding to FIG. 5 (basic structure of cell) during a manufacturing step (P-type body contact region impurity introduction step);

FIG. 18 is a cross-sectional view of the unit cell region corresponding to FIG. 5 (basic structure of cell) during a manufacturing step (step of forming a metal source electrode and the like);

FIG. 19 is a cross-sectional view of the unit cell region corresponding to FIG. 5 (basic structure of cell) during a manufacturing step (back grinding step);

FIG. 20 is a cross-sectional view of the unit cell region corresponding to FIG. 5 (basic structure of cell) during a manufacturing step (step of forming a back-surface electrode and the like);

FIG. 21 is a detailed cross-sectional view of the unit cell region 20 of FIG. 3, that is, an active cell structure (thick-film structure of an underlying insulating film) of a power MOSFET which is one example of a semiconductor device according to the one embodiment (Modification Example 1) of the present application;

FIG. 22 is a cross-sectional view of the unit cell region corresponding to FIG. 21 (thick-film structure of an underlying insulating film) during a manufacturing step (step of burying an insulating film underlying a gate electrode);

FIG. 23 is a cross-sectional view of the unit cell region corresponding to FIG. 21 (thick-film structure of an underlying insulating film) during a manufacturing step (step of etching back the insulating film underlying the gate electrode);

FIG. 24 is a cross-sectional view of the unit cell region corresponding to FIG. 21 (thick-film structure of an underlying insulating film) during a manufacturing step (gate oxidation step);

FIG. 25 is a cross-sectional view of the unit cell region corresponding to FIG. 21 (thick-film structure of an underlying insulating film) during a manufacturing step (gate polysilicon burying step);

FIG. 26 is a cross-sectional view of the unit cell region corresponding to FIG. 21 (thick-film structure of an underlying insulating film) during a manufacturing step (gate polysilicon etch-back step);

FIG. 27 is a cross-sectional view of the unit cell region corresponding to FIG. 21 (thick-film structure of an underlying insulating film) during a manufacturing step (interlayer insulating film burying step);

FIG. 28 is a cross-sectional view of the unit cell region corresponding to FIG. 21 (thick-film structure of an underlying insulating film) during a manufacturing step (planarization step);

FIG. 29 is a detailed cross-sectional view of the unit cell region 20 of FIG. 3, that is, an active cell structure (dummy gate electrode-added structure) of the power MOSFET which is one example of the semiconductor device according to the one embodiment (Modification Example 2) of the present application;

FIG. 30 is a cross-sectional view of the unit cell region corresponding to FIG. 29 (dummy gate electrode-added structure) during a manufacturing step (dummy gate polysilicon etch-back step);

FIG. 31 is a cross-sectional view of the unit cell region corresponding to FIG. 29 (dummy gate electrode-added structure) during a manufacturing step (step of forming an insulating film crossing a trench gate);

FIG. 32 is a cross-sectional view of the unit cell region corresponding to FIG. 29 (dummy gate electrode-added structure) during a manufacturing step (gate polysilicon burying step);

FIG. 33 is a cross-sectional view of the unit cell region corresponding to FIG. 29 (dummy gate electrode-added structure) during a manufacturing step (gate polysilicon etch-back step);

FIG. 34 is a cross-sectional view of the unit cell region corresponding to FIG. 29 (dummy gate electrode-added structure) during a manufacturing step (interlayer insulating, film burying step);

FIG. 35 is a cross-sectional view of the unit cell region corresponding to FIG. 29 (dummy gate electrode-added structure) during a manufacturing step (planarization step);

FIG. 36 shows a layout of terminals of IGBT (insulated gate bipolar transistor) which is one example of another active device to which each embodiment described herein can be applied;

FIG. 37 is a cross-sectional view of a unit cell of the IGBT, corresponding to FIG. 5, which is the above-described one example of another active device to which each embodiment described herein can be applied;

FIG. 38 is a top layout of a single chip of an integrated power-source element on which a major portion of the circuit elements in FIG. 1 have been integrated;

FIG. 39 is a fragmentary schematic cross-sectional view of a chip corresponding to the Y-Y′ cross-section of FIG. 38;

FIG. 40 is a data plotted diagram showing the relationship, in a trench-gate vertical-channel type power MOSFET, between cell size and on-state resistance; and

FIG. 41 is a cross-sectional view of a unit cell corresponding to FIG. 5 for explaining the relationship among elements around a trench in each embodiment of the present application.

### DETAILED DESCRIPTION

First, typical embodiments of the invention disclosed herein will next be outlined.

1. A semiconductor device including: (a) a semiconductor substrate having a first main surface and a second main surface; (b) a first-conductivity type drift region provided in the semiconductor substrate; (c) an active region provided on the first main surface; and (d) many unit cell regions provided in the active region when viewed planarly, the unit cell regions each penetrating through the drift region from the upper portion of the first main surface and including: (d1) a body region provided in the semiconductor substrate on the first main surface side in the drift region and having a second conductivity type, which is a conductivity type opposite to the first conductivity type; (d2) a trench provided in the first main surface of the semiconductor substrate and penetrating through the body region to reach the drift region; (d3) a gate electrode provided in the trench via a gate insulating film; (d4) an interlayer insulating film provided on the gate electrode; (d5) a first-conductivity type in-substrate source region provided in the surface of the semiconductor substrate on the first main surface side but outside the trench so as to come into contact with the gate insulating film; (d6) a poly Si source region provided on both sides of the interlayer insulating film so as to come into contact with an upper portion of the in-substrate source region; and (d7) a metal source electrode provided on the first main surface of the semiconductor substrate so as to cover the interlayer insulating film and the poly Si source region. In the above-described semiconductor device, the width of the interlayer insulating film and the width of the trench are substantially equal.

2. In the semiconductor device as described above in 1, the gate electrode is a polysilicon electrode.

3. In the semiconductor device as described above in 1 or 2, the poly Si source region is a sidewall of the interlayer insulating film.

4. In the semiconductor device as described above in any of 1 to 3, an impurity having the same conductivity type as that of the in-substrate source region has been doped in the poly Si source region.

5. In the semiconductor device as described above in any of 1 to 4, the drift region is an N-type epitaxy region.

6. In the semiconductor device as described above in any of 1 to 5, an N type drain region is provided on the second main surface side of the semiconductor substrate.

7. In the semiconductor device as described above in any of 1 to 6, the thickness of the gate insulating film at the lower end of the trench is greater than the thickness of a portion of the gate insulating film contiguous to the body region.

8. In the semiconductor device as described above in any of 1 to 7, a dummy gate electrode is provided below the gate electrode and at the lower end portion of the trench via the gate insulating film.

9. In the semiconductor device as described above in 8, the dummy gate electrode is a polysilicon dummy gate electrode.

10. In the semiconductor device as described above in 8 or 9, the dummy gate electrode is adjusted to have a potential substantially equal to that of the metal source electrode.

11. A semiconductor device, including: (a) a semiconductor substrate having a first main surface and a second main surface; (b) a first-conductivity type drift region provided in the semiconductor substrate; (c) an active region provided on the first main surface; and (d) many unit cell regions provided in the active region when viewed planarly, the unit cell regions each penetrating through the drift region from the upper portion of the first main surface and including: (d1) a body region provided in the semiconductor substrate on the first main surface side of the drift region and having a second conductivity type, which is a conductivity type opposite to the first conductivity type; (d2) a trench provided in the first main surface of the semiconductor substrate and penetrating through the body region to reach the drift region; (d3) a gate electrode provided in the trench via a gate insulating film; (d4) an interlayer insulating film provided on the gate electrode; (d5) a first-conductivity type in-substrate source region provided in the surface of the semiconductor substrate on the first main surface side but outside the trench so as to come into contact with the gate insulating film; (d6) a poly Si source region provided on both sides of the interlayer insulating film so as to come into contact with an upper portion of the in-substrate source region; and (d7) a metal source electrode provided on the first main surface of the semiconductor substrate so as to cover the interlayer insulating film and the poly Si source region. In the above-described semiconductor device, the in-substrate source region and the poly Si source region are provided along substantially flat sidewalls of the trench.

12. In the semiconductor device as described above in 11, the gate electrode is a polysilicon electrode.

13. In the semiconductor device as described above in 11 or 12, the poly Si source region is a sidewall of the interlayer insulating film.

14. In the semiconductor device as described above in any of 11 to 13, an impurity having the same conductivity type as that of the in-substrate source region has been doped in the poly Si source region.

15. In the semiconductor device as described above in any of 11 to 14, the drift region is an N-type epitaxy region.

16. In the semiconductor device as described above in any of 11 to 15, an N type drain region is provided on the second main surface side of the semiconductor substrate.

17. In the semiconductor device as described above in any of 11 to 16, the thickness of the gate insulating film at the lower end of the trench is greater than the thickness of a portion of the gate insulating film contiguous to the body region.

18. In the semiconductor device as described above in any of 11 to 17, a dummy gate electrode is provided below the gate electrode and at the lower end portion of the trench via the gate insulating film.

19. In the semiconductor device as described above in 18, the dummy gate electrode is a polysilicon dummy gate electrode.

20. In the semiconductor device as described above in 18 or 19, the dummy gate electrode is adjusted to have a potential substantially equal to that of the metal source electrode.

21. In the semiconductor device as described above in any one of 1 to 20, the interlayer insulating film protrudes from the upper end of the trench.

22. The semiconductor device as described above in any one of 1 to 21, which is a power MOSFET.

Further embodiments of the invention disclosed herein will next be described.

1. A manufacturing method of a semiconductor device having: (a) a semiconductor substrate having a first main surface and a second main surface; (b) a first-conductivity type drift region provided in the semiconductor substrate; (c) an active region provided on the first main surface; and (d) many unit cell regions provided in the active region when viewed planarly, the unit cell regions each penetrating through the drift region from the upper portion of the first main surface and having: d1) a body region provided in the semiconductor substrate on the first main surface side of the drift region and having a second conductivity type, which is a conductivity type opposite to the first conductivity type; (d2) a trench provided in the first main surface of the semiconductor substrate and penetrating through the body region to reach the drift region; (d3) a gate electrode provided in the trench via a gate insulating film; (d4) an interlayer insulating film provided on the gate electrode; (d5) a first-conductivity type in-substrate source region provided in the surface of the semiconductor substrate on the first main surface side but outside the trench so as to come into contact with the gate insulating film; (d6) a poly Si source region provided on both sides of the interlayer insulating film so as to come into contact with an upper portion of the in-substrate source region; and (d7) a metal source electrode provided on the first main surface of the semiconductor substrate so as to cover the interlayer insulating film and the poly Si source region. The above-described manufacturing method includes the following steps: (x1) forming the trench, (x2) forming the gate insulating film on at least the inner surface of the trench; (x3) burying the gate electrode in the trench while having the gate insulating film on the inner surface of the trench; (x4) burying the interlayer insulating film on the gate electrode in the trench, (x5) after the step (x4), etching the first main surface of the semiconductor substrate outside the trench in self alignment to protrude the interlayer insulating film from the upper end of the trench; (x6) forming, in self alignment, a poly Si sidewall doped with a first conductivity type impurity on both sides of the protruded interlayer insulating film; (x7) forming the in-substrate source region in the first main surface of the semiconductor substrate contiguous to the poly Si sidewall by using the first conductivity type impurity supplied from the poly Si sidewall; and (x8) after the step (x7), forming the metal source electrode on the first main surface of the semiconductor substrate so as to cover the interlayer insulating film and the poly Si source region.

2. In the manufacturing method of a semiconductor device as described above in 1, the gate electrode is a polysilicon electrode.

3. In the manufacturing method of a semiconductor device as described above in 1 or 2, an N type drain region is provided on the second main surface side of the semiconductor substrate.

Still further embodiments of the invention disclosed herein will next be outlined.

1. A semiconductor device including: (a) a semiconductor substrate having a first main surface and a second main surface; (b) a first-conductivity type drift region provided in the semiconductor substrate; (c) an active region provided on the first main surface; and (d) many unit cell regions provided in the active region when viewed planarly, the unit cell regions each penetrating through the drift region from the upper portion of the first main surface and including: (d1) a body region provided in the semiconductor substrate on the first main surface side of the drift region and having a second conductivity type, which is a conductivity type opposite to the first conductivity type; (d2) a trench provided in the first main surface of the semiconductor substrate and penetrating through the body region to reach the drift region; (d3) a gate electrode provided in the trench via a gate insulating film; (d4) an interlayer insulating film provided on the gate electrode; (d5) a first-conductivity type in-substrate source region provided in the surface of the semiconductor substrate on the first main surface side but outside the trench so as to come into, contact with the gate insulating film; (d6) a poly Si source region provided on both sides of the interlayer insulating film so as to come into contact with an upper portion of the in-substrate source region; and (d7) a metal source electrode provided on the first main surface of the semiconductor substrate so as to cover the interlayer insulating film and the poly Si source region. In the above-described semiconductor device, the lower portion of the interlayer insulating film is housed in the trench.

2. In the semiconductor device as described above in 1, the gate electrode is a polysilicon electrode.

3. In the semiconductor device as described above in 1 or 2, the poly Si source region is a sidewall of the interlayer insulating film.

4. In the semiconductor device as described above in any one of 1 to 3, an impurity having the same conductivity type as that of the in-substrate source region has been doped in the poly Si source region.

5. In the semiconductor device as described above in any one of 1 to 4, the drift region is an N type epitaxy region.

6. in the semiconductor device as described above in any one 1 to 5, an N type drain region is provided on the second main surface side of the semiconductor substrate.

7. In the semiconductor device as described above in any one 1 to 6, the thickness of the gate insulating film at the lower end of the trench is greater than the thickness of the gate insulating film contiguous to the body region.

8. In the semiconductor device as described above in any of 1 to 7, a dummy gate electrode is provided below the gate electrode and at the lower end portion of the trench via the gate insulating film.

9. In the semiconductor device as described above in 8, the dummy gate electrode is a polysilicon dummy gate electrode.

10. In the semiconductor device as described above in 8 or 9, the dummy gate electrode is adjusted to have a substantially equal potential to that of the metal source electrode.

11. A semiconductor device including: (a) a semiconductor substrate having a first main surface and a second main surface; (b) a first-conductivity type drift region provided in the semiconductor substrate; (c) an active region provided on the first main surface; and (d) many unit cell regions provided in the active region when viewed planarly, the unit cell regions each penetrating through the drift region from the upper portion of the first main surface and having: (d1) a body region provided in the semiconductor substrate on the first main surface side of the drift region and having a second conductivity type, which is a conductivity type opposite to the first conductivity type; (d2) a trench provided in the first main surface of the semiconductor substrate and penetrating through the body region to reach the drift region; (d3) a gate electrode provided in the trench via a gate insulating film; (d4) an interlayer insulating film provided on the gate electrode; (d5) a first-conductivity type in-substrate source region provided in the surface of the semiconductor substrate on the first main surface side but outside the trench so as to come into contact with the gate insulating film; (d6) a poly Si source region provided on both sides of the interlayer insulating film so as to come into contact with an upper portion of the in-substrate source region; and (d7) a metal source electrode provided on the first main surface of the semiconductor substrate so as to cover the interlayer insulating film and the poly Si source region. In the above-described semiconductor substrate, the interlayer insulating film has the same width at the upper portion and the lower portion thereof.

12. In the semiconductor device as described above in 11, the gate electrode is a polysilicon electrode.

13. In the semiconductor device as described above in 11 or 12, the poly Si source region is a sidewall of the interlayer insulating film.

14. In the semiconductor device as described above in any one of 11 to 13, an impurity having the same conductivity type as that of the in-substrate source region has been doped in the poly Si source region.

15. In the semiconductor device as described above in any one of 11 to 14, the drift region is an N type epitaxy region.

16. In the semiconductor device as described above in any one 11 to 15, an N type drain region is provided on the second main surface side of the semiconductor substrate.

17. In the semiconductor device as described above in any one 11 to 16, the thickness of the gate insulating film at the lower end of the trench is greater than the thickness of the gate insulating film contiguous to the body region.

18. In the semiconductor device as described above in any of 11 to 17, a dummy gate electrode is provided below the gate electrode and at the lower end portion of the trench via the gate insulating film.

19. In the semiconductor device as described above in 18, the dummy gate electrode is a polysilicon dummy gate electrode.

20. In the semiconductor device as described above in 18 or 19, the dummy gate electrode is adjusted to have a substantially equal potential to that of the metal source electrode.

21. In the semiconductor device as described above in any one of 1 to 20, the interlayer insulating film protrudes from the upper end of the trench.

22. The semiconductor device as described above in any one of 1 to 21, which is a power MOSFET.

### [Explanation of Description Manner, Basic Terms, and Usage in The Present Application]

1. In the present application, a description in embodiments may be made after divided in a plurality of parts or sections if necessary for convenience's sake. These parts or sections are not independent from each other, but they may each be a part of a single example or one of them may be a partial detail of the other or a modification example of a part or whole of the other one unless otherwise specifically indicated. In principle, description on a portion similar to that described before is not repeated. Moreover, when a reference is made to constituent elements in the embodiments, they are not essential unless otherwise specifically indicated, limited to the number theoretically, or principally apparent from the context that they are essential.

Further, the term “semiconductor device” as used herein means mainly a simple device of various transistors (active elements) or a device obtained by integrating such a simple device as a main component with a resistor, a capacitor, and the like on a semiconductor chip or the like (for example, a single crystal silicon substrate). Typical examples of the various transistors include MISFET (metal insulator semiconductor field effect transistor) typified by MOSFET (metal oxide semiconductor field effect transistor). Here, typical examples of various simple transistors include power MOSFET and IGBT (insulated gate bipolar transistor). Further, power active elements such as power MOSEFT described herein are normally-off type elements unless otherwise specifically indicated.

The term “semiconductor active element” as used herein means a transistor, a diode, or the like.

It is cumbersome to use “MOS” and “MIS” properly so that the term “MOS” is used unless otherwise specifically indicated, even if a substance other than an oxide is used as an insulating film.

2. Similarly, with regard to any material, any composition or the like in the description of the embodiments, the term “X made of A” or the like does not exclude X having, as one of the main constituent components thereof, an element other than A unless otherwise specifically indicated or principally apparent from the context that it is not. For example, the term “X made of A” means that “X has A as a main component thereof”. It is needless to say that, for example, the term “silicon member” is not limited to a member made of pure silicon but also means a member made of a SiGe alloy or another multi-element alloy having silicon as a main component or a member containing an additive in addition. Similarly, the term “silicon oxide film”, “silicon oxide-based insulating film”, or the like is not limited to a relatively pure undoped silicon oxide (undoped silicon dioxide) but needless to say, it embraces FSG (fluorosilicate glass) film, TEOS-based silicone oxide film, SiOC (silicon oxycarbide) film, or carbon-doped silicon oxide film, a thermal oxidation film such as OSG (organosilicate glass) film, PSG (phosphorus silicate glass) film, or BPSG (borophosphosilicate glass) film, a CVD oxide film, silicon oxide films obtained by the method of application such as SOG (spin on glass) film and nano-clustering silica (NSC) film, silica-based low-k insulating films (porous insulating films) obtained by introducing pores into members similar to them, and composite films each made of any one of the above-mentioned films as a principal configuring element and another silicon-based insulating film.

In addition, silicon-based insulating films ordinarily used in the semiconductor field like silicon oxide-based insulating films are silicon nitride-based insulating films. Materials which belong to such a group include SiN, SiCN, SiNH, and SiCNH. The term “silicon nitride” embraces both SiN and SiNH unless otherwise specifically indicated that it is not. Similarly, the term “SiCN” embraces both SiCN and SiCNH unless otherwise specifically indicated that it is not.

Incidentally, SiC has similar properties to SiN, but in most cases, SiON should be classified rather as a silicon oxide-based insulating film.

3. Preferred examples of the shape, position, attribute, and the like will be shown below, however, it is needless to say that the shape, position, attribute, and the like are not strictly limited to these preferred examples unless otherwise specifically indicated or apparent from the context that they are not.

4. When a reference is made to a specific number or amount, the number or amount may be greater than or less than the specific number or amount unless otherwise specifically indicated, limited to the specific number or amount theoretically, or apparent from the context that it is not.

5. The term “wafer” usually means a single crystal silicon wafer over which a semiconductor device (which may be a semiconductor integrated circuit device or an electronic device) is to be formed. It is however needless to say that it embraces a composite wafer of an insulating substrate and a semiconductor layer or the like, such as an epitaxial wafer, a SOI substrate, or an LCD glass substrate.

6. The term “field plate” or “dummy gate” means a conductor film pattern coupled to a source potential or a potential equivalent thereto and extending via an insulating film to an upper portion of the surface (device surface) in the drift region or extending in the trench.

7. In the structure of IGBT, a semiconductor region having a conductivity type opposite to that of a drift region is placed in the drain side of a typical vertical type power MOSFET. Accordingly, the gate and source of IGBT have a substantially similar structure to those of a vertical type power MOSFET, but in practice, a portion corresponding to a source terminal is called an emitter terminal based on the terminal-corresponding relationship with a bipolar transistor. In the present application, however, in consideration of physical modes, elements of IGBT corresponding to the source of a vertical type power MOSFET are called “source region”, “source electrode”, and “source terminal, respectively, unless otherwise specifically indicated.

### Details of Embodiments

Embodiments will next be described more specifically. In all the drawings, the same or like members will be identified by the same or like symbols or reference numerals and overlapping, descriptions will be omitted in principle.

In the accompanying drawings, hatching or the like is sometimes omitted even from the cross-section when it makes the drawing cumbersome and complicated or when a member can be discriminated clearly from a vacant space. In relation thereto, even a two-dimensionally closed hole may have a background outline thereof omitted when it is obvious from the description or the like that the hole is two-dimensionally closed and so on. On the other hand, even a portion other than a cross section may be hatched to clearly show that the hatched portion is not a vacant space.

Examples of the present applicant's prior patent application on a DC-DC converter to be used for a computer power source or the like include Japanese Patent Laid-Open No. 2009-22106 (or U.S. Patent Laid-Open No. 2009-15224 corresponding thereto) and Japanese Patent Laid-Open No. 2010-16035 (or U.S. Patent Laid-Open No. 2010-1790 corresponding thereto).

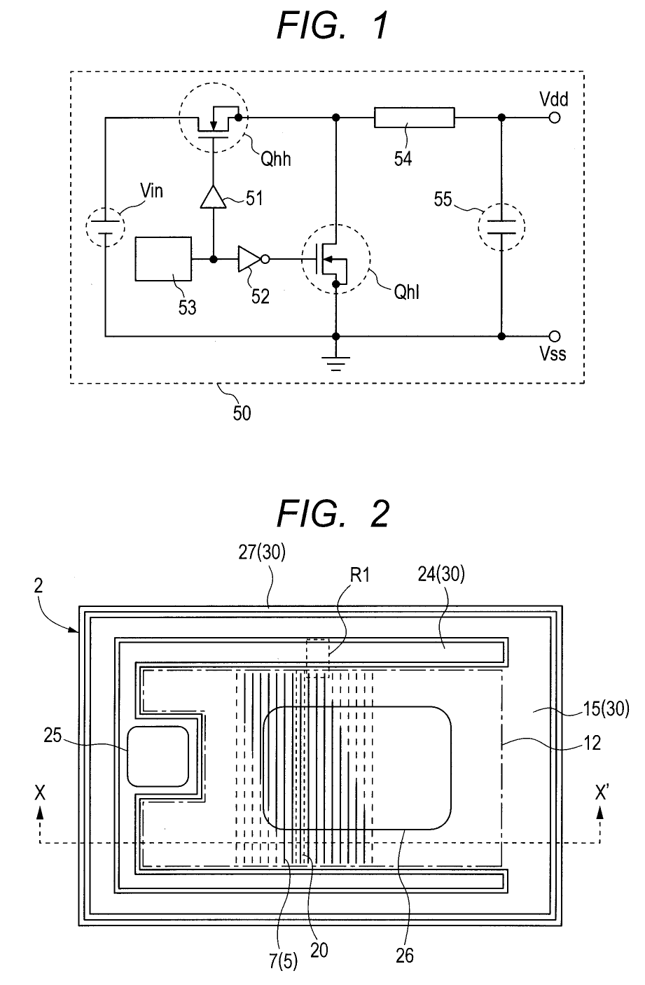

1. Description of main application fields of semiconductor devices according to embodiments of the present application (mainly, FIG. 1). As a power MOSFET or the like to be described in the following embodiments, those suited for a high side switch in a DC-DC converter or the like are mainly exemplified, but needless to say, they are also effective for a low side switch in high-frequency operation.

FIG. 1 is a schematic circuit diagram showing the circuit configuration of a DC-DC converter for computer which is a main application field of a semiconductor device of each embodiment according to the present application. Based on it, the main application field and the like of the semiconductor device of each embodiment of the present application will next be described.

As illustrated in FIG. 1, the power supply to a microprocessor or the like in PC (personal computer) is usually performed, for example, at a voltage as low as about 1V by using a VRM (voltage regulator module) such as DC-DC converter 50 while using, as a constant voltage source (DC source Vin), a direct current of about 17V obtained by reducing and rectifying an alternating current of from about 90 to 300V. An amount of the current sometimes exceeds 100 ampere. From a control circuit 53, a switching signal of, for example, about 200 kHz (a typical range is from about 300 kHz to about 500 kHz, while a range in the past or near future is from about 20 kHz to about 1 MHz) is emitted and complementary pulse signals drive a high side SW power MOSFET (Qhh) and a low side SW power MOSFET (Qhl) through a high side driver 51 and a low side driver 52, respectively. When the high side SW power MOSFET (Qhh) is ON, a current is supplied through the high side SW power MOSFET (Qhh), passes through a smoothing circuit comprised of an output smoothing inductor 54, an output smoothing condenser 55, and the like, and is then supplied to a microprocessor and the like from a power output terminal Vdd and a ground terminal Vss. On the other hand, when the high side SW power MOSFET (Qhh) is OFF, the low side SW power MOSFET (Qhl) is ON and a current is supplied through a current pathway running from the low side SW power MOSFET (Qhl) toward the output smoothing inductor 54. The voltage at this time is controlled by the length of time that the high side SW power MOSFET (Qhh) is ON.

2. Description on the outline of the structure of a semiconductor chip of the semiconductor device according to each embodiment (mainly, from FIG. 2 to FIG. 4). In this section, the structure of a power MOSFET particularly suited for the high side switch or the like described in Section 1 will be outlined.

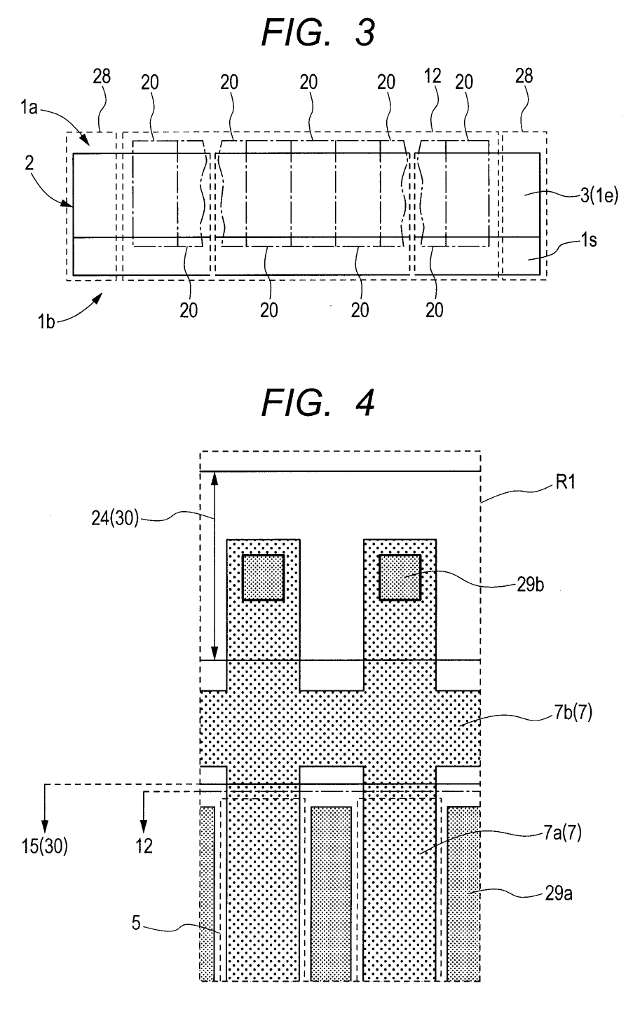

FIG. 2 is an overall top view of a semiconductor chip of a power MOSFET which is one example of the semiconductor device of each embodiments of the present application. FIG. 3 is a schematic cross-sectional view of the chip corresponding to the X-X′ cross-section of FIG. 2. FIG. 4 is an enlarged top view of the cutout region R1 of the gate electrode lead-out portion of FIG. 2. Based on these drawings, the structure of a semiconductor chip of the semiconductor device according to each embodiment of the present application will be outlined. It is however to be noted that in FIG. 2, the dimension of the peripheral structure is exaggerated in order to describe the overall structure of the upper surface of the chip. In addition, the number of trench gates shown in the drawing is much less than the actual number, because the actual number of trench gates is so large as to prevent visual recognition. Further, the active region is filled with the trench gates and indication of all of them prevents viewing of the drawing so that only a portion (at the center) is indicated.

First, the upper surface structure of a semiconductor chip is described. As illustrated in FIG. 2, a semiconductor chip 2 has, at the peripheral end thereof, a guard ring 27 (made of the same layer as, for example, an aluminum-based metal electrode film 30) in a ring form surrounding therewith the end portion and almost all the portion inside of the guard ring is occupied by a gate wiring portion 24 and a metal source electrode 15 (they are also comprised of the same layer as that of, for example, the aluminum-based metal electrode film 30). A portion of the gate wiring portion 24 is a gate pad portion 25 for attaching a bonding wire and the like and a portion of a metal source electrode 15 near the center is a source pad 26 for also attaching a bonding wire and the like. A region below the metal source electrode 15 which is the main portion of the upper surface of the semiconductor chip 2 is an active region 12 (active cell region) filled with unit cell regions 20 each in a strip form viewed planarly (repeating cycle of the unit cells, that is, the width of the unit cell is, for example, about 0.4 micrometer) and a gate polysilicon film (that is, a gate electrode 7) is buried in a trench 5, for example, in linear form.

Next, the X-X′ cross-section of FIG. 2 is shown in FIG. 3. As illustrated in FIG. 3, the lower half portion of the semiconductor chip 2 is a relatively heavily doped N type semiconductor substrate region is (for example, an N type single-crystal silicon substrate, that is, an N type drain region). On the side of the surface 1a (first main surface) of the N type semiconductor substrate region is, that is, the side opposite to the back surface 1b, an N-epitaxial region 1e having a thickness, which varies depending on the withstand voltage required, is provided. The main portion of it corresponds to an N-drift region 3. The semiconductor chip 2 has, at the periphery thereof, an edge termination region 28 and most of the inner region of the semiconductor chip 3 is occupied by the active region 12. This active region 12 is filled with the unit cell regions 20 planarly in a strip form (sterically, in a cuboid form).

Next, details of the cutout region R1 of the gate electrode lead-out portion in FIG. 2 is shown in FIG. 4. As shown in FIG. 4, the active region 12 is provided with trenches 5, which are planarly in a strip form, and trench gate electrodes 7a (gate polysilicon films 7) are buried in the trenches, for example, at regular intervals. The trench gate electrodes 7a have therebetween a source contact portion 29a. The upper portion of the active region 12 including the upper portions of the trench gate electrode 7a and the source contact portion 29a is covered with the metal source electrode 15 (aluminum-based metal electrode film 30). The polysilicon gate electrode 7 (trench gate electrode 7a) extends outside the active region 12 and becomes a gate lead-out polysilicon wiring portion 7b. It is coupled to a gate wiring portion 24 (aluminum-based metal electrode film 30) via a gate contact portion 29b.

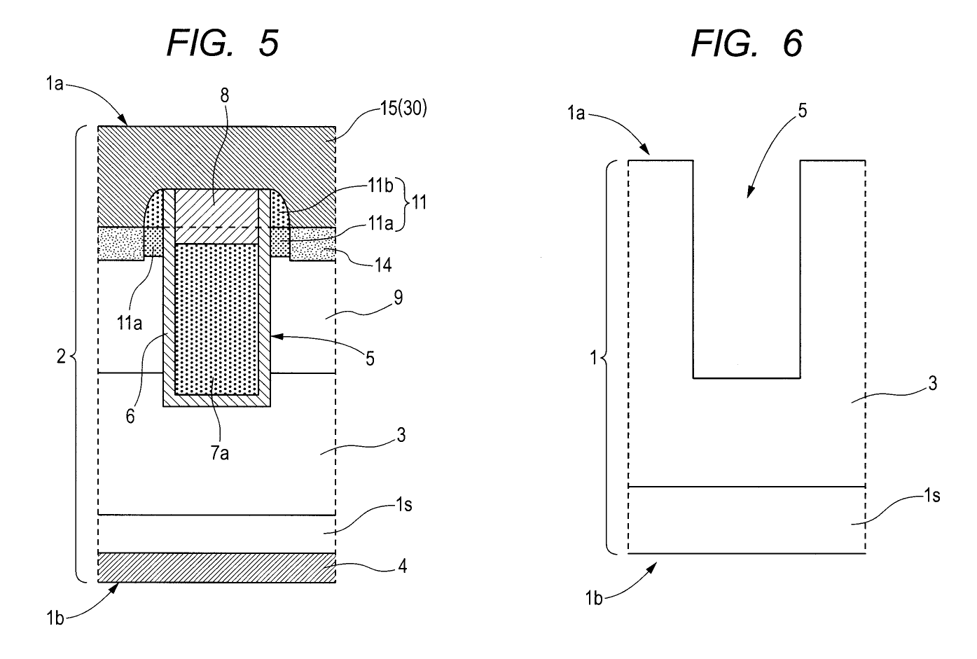

3. Description on the active cell structure (basic structure) of a power MOSFET which is one example of the semiconductor device according to one embodiment of the present application (mainly, FIG. 5). In this section, a specific example of the unit cell region 20 described in Section 2 will be described.

FIG. 5 is a detailed cross-sectional view of the active cell structure (basic structure of the cell) of a power MOSFET, which is one example of the semiconductor device according to one embodiment of the present application. Based on this drawing, the active cell structure (basic structure) of a power MOSFET which is one example of the semiconductor device according to one embodiment of the present application will be described.

As shown in FIG. 5, a back-surface metal electrode 4 (for example, a drain electrode) is provided on the back surface 1b side of the N type semiconductor substrate region is (N type drain region) of the semiconductor chip 2, while an N-drift region 3 is provided on the surface 1a side of the N-type semiconductor substrate region is. A P-type body region 9 is provided on the surface 1a side of the N-drift region 3 and an N type in-substrate source region 11a configuring a portion of a source region 11 and a P type body contact region 14 are provided in the semiconductor surface region on the surface 1a side of the N-drift region 3. A trench 5 penetrating through the P type body region 9 from the surface 1a (first main surface) side of the semiconductor substrate 2 and reaching the N-drift region 3 is provided. The trench 5 (more precisely, a portion of a trench filling member protrudes from the upper portion of the trench) is filled with a trench gate electrode 7a such as polysilicon and an interlayer insulating film, in the order of mention, via a gate insulating film 6. The trench filling member protruding from the trench 5 has therearound a poly Si source region 11b (sidewall) in a sidewall form. This poly Si source region 11b (heavily-doped N type impurity dope) and the N type in-substrate source region 11a (in this example, the impurity in this region has been supplied from the poly Si source region 11b) configure the source region 11. Further, the semiconductor substrate 2 has, on the surface 1a side thereof, metal source electrode 15 (obtained by patterning an aluminum-based metal electrode film 30 and the like) and it covers therewith the semiconductor region, the trench filling member and the sidewall.

4. Description on a manufacturing process of a power MOSFET which is one example of the semiconductor device according to the one embodiment of the present application (mainly from FIG. to FIG. 20). In this section, one example of a manufacturing method of a device having the structure corresponding to that of Section 3 will be described.

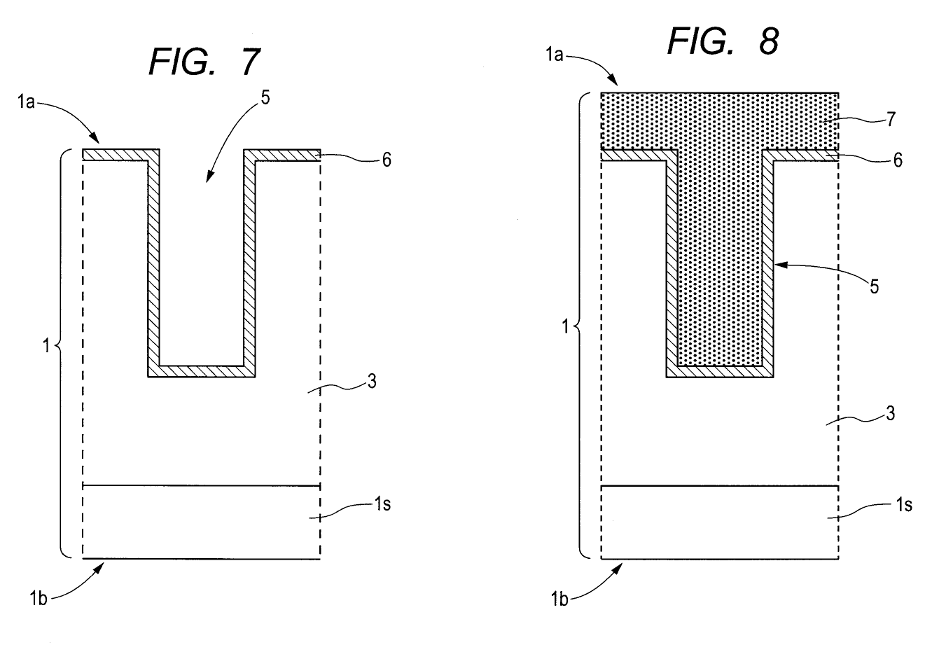

FIG. 6 is a cross-sectional view of the unit cell region corresponding to FIG. 5 (basic structure of cell) during a manufacturing step (trench formation step). FIG. 7 is a cross-sectional view of the unit cell region corresponding to FIG. 5 (basic structure of cell) during a manufacturing step (gate oxidation step). FIG. 8 is a cross-sectional view of the unit cell region corresponding to FIG. 5 (basic structure of cell) during a manufacturing step (gate polysilicon burying step).

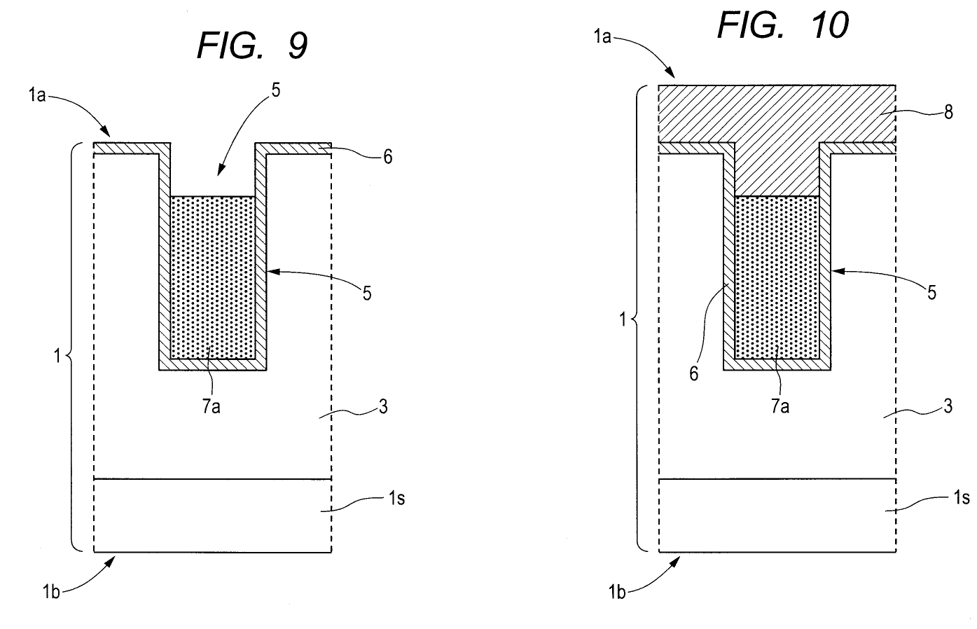

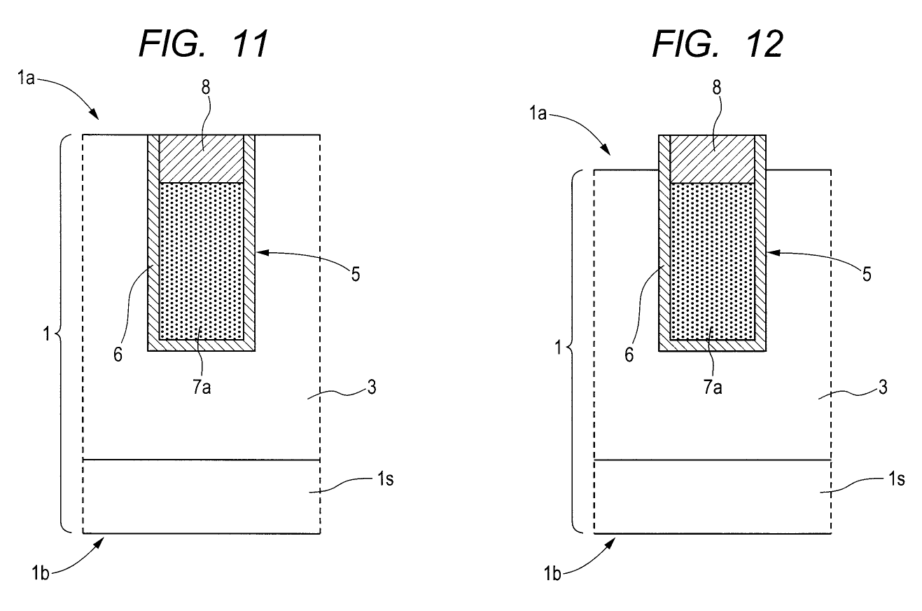

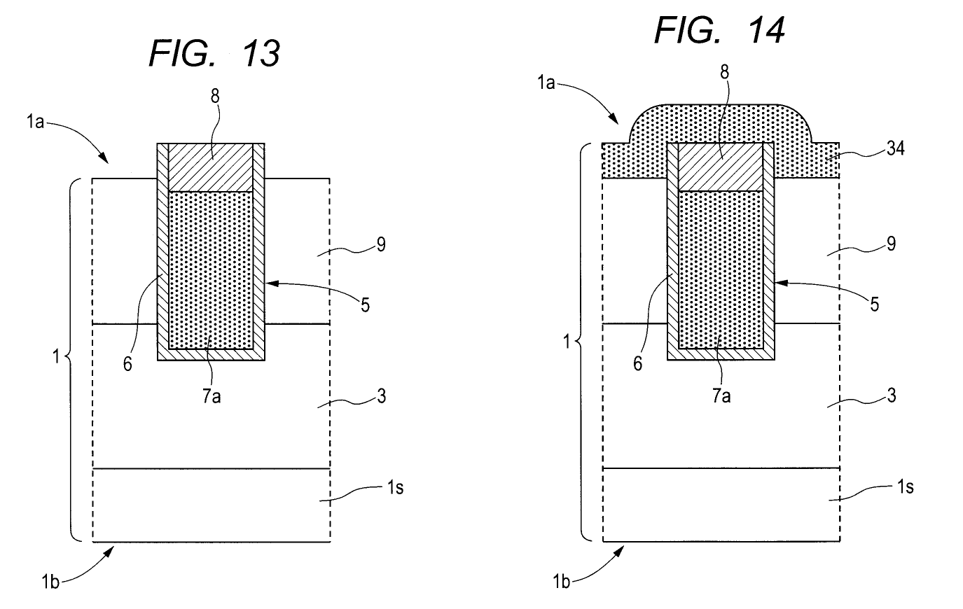

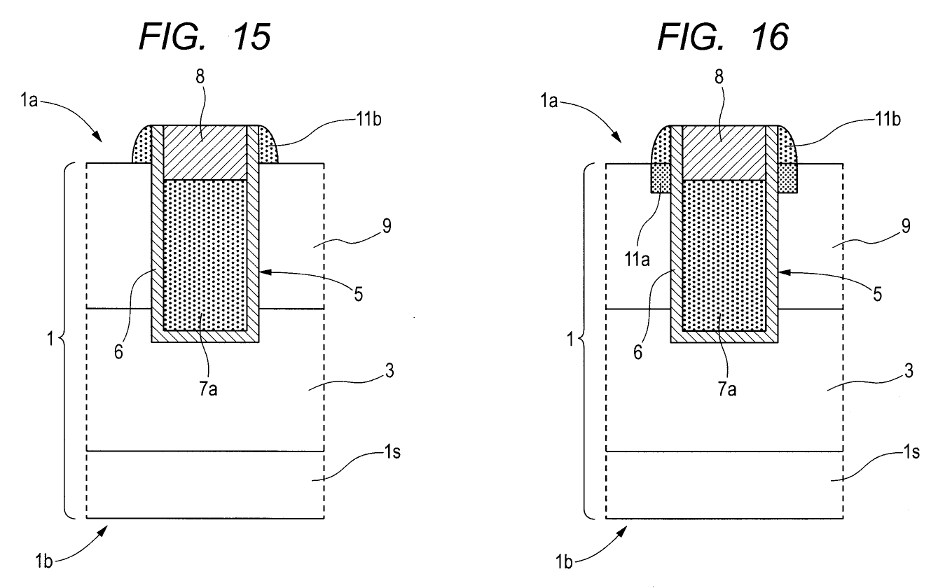

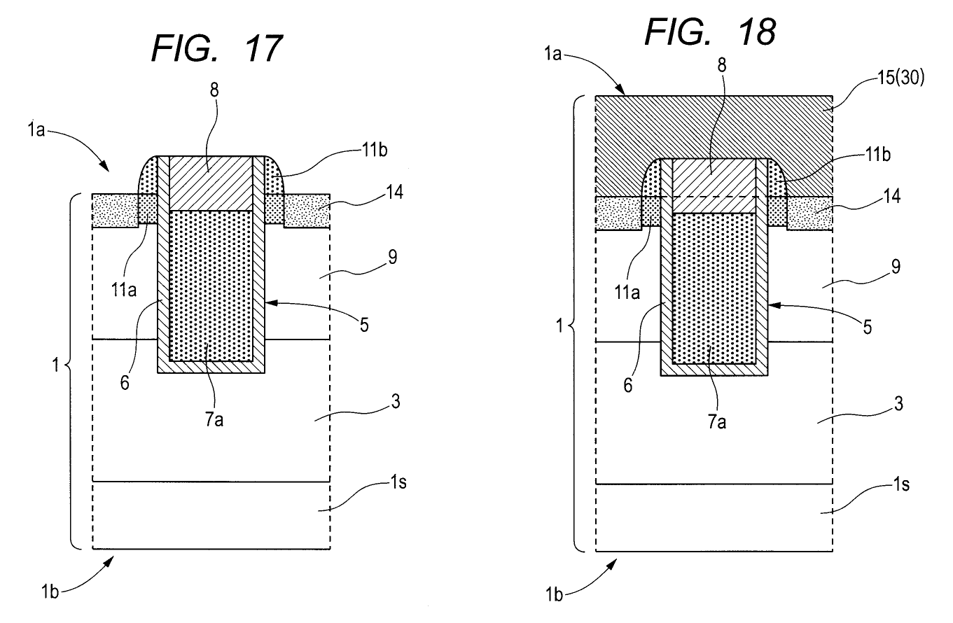

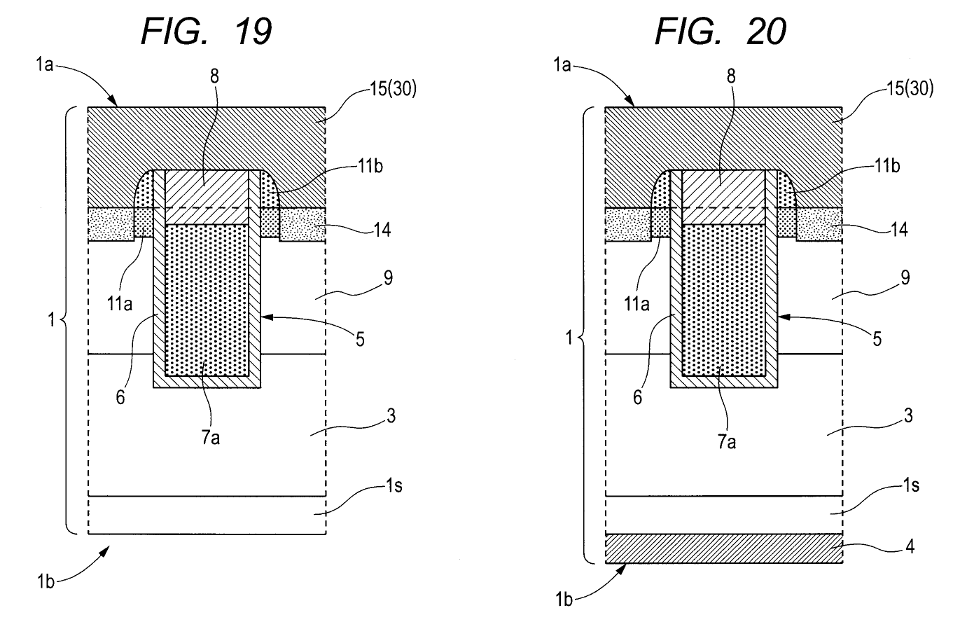

FIG. 9 is a cross-sectional view of the unit cell region corresponding to FIG. 5 (basic structure of cell) during a manufacturing step (gate polysilicon etch-back step). FIG. 10 is a cross-sectional view of the unit cell region corresponding to FIG. 5 (basic structure of cell) during a manufacturing step (interlayer insulating film burying step). FIG. 11 is a cross-sectional view of the unit cell region corresponding to FIG. 5 (basic structure of cell) during a manufacturing step (planarization step). FIG. 12 is a cross-sectional view of the unit cell region corresponding to FIG. 5 (basic structure of cell) during a manufacturing step (substrate etching step). FIG. 13 is a cross-sectional view of the unit cell region corresponding to FIG. 5 (basic structure of cell) during a manufacturing step (P-type body region introduction step). FIG. 14 is a cross-sectional view of the unit cell region corresponding to FIG. 5 (basic structure of cell) during a manufacturing step (sidewall polysilicon film formation step). FIG. 15 is a cross-sectional view of the unit cell region corresponding to FIG. 5 (basic structure of cell) during a manufacturing step (sidewall formation step). FIG. 16 is a cross-sectional view of the unit cell region corresponding to FIG. 5 (basic structure of cell) during a manufacturing step (source impurity introduction step). FIG. 17 is a cross-sectional view of the unit cell region corresponding to FIG. 5 (basic structure of cell) during a manufacturing step (P-type body contact region impurity introduction step). FIG. 18 is a cross-sectional view of the unit cell region corresponding to FIG. 5 (basic structure of cell) during a manufacturing step (step of forming a metal source electrode and the like). FIG. 19 is a cross-sectional view of the unit cell region corresponding to FIG. 5 (basic structure of cell) during a manufacturing step (back grinding step). FIG. 20 is a cross-sectional view of the unit cell region corresponding to FIG. 5 (basic structure of cell) during a manufacturing step (step of forming a back-surface electrode and the like). Based on these drawings, the manufacturing process of a power MOSFET which is one example of the semiconductor device according to the one embodiment of the present application will next be described.

A 200-φ N type silicon single crystal wafer is with surface orientation of (100) (it may be a wafer with 300φ, 450φ or another diameter and has a resistivity of for example, from about 1 to 2 mΩ·cm) is prepared. An N type (for example, phosphorus-doped and with a resistivity for example, from about 0.1 to 0.3 mΩ·cm) silicon epitaxial layer is deposited with a thickness of about 2 micrometer (a range of, for example, from about 1.3 to 3.3 micrometer), depending on a required withstand voltage (here, a source-drain withstand voltage is set at about 30V, as one example) to obtain a wafer 1 with an epitaxial layer.

Next, for example, a silicon oxide film with a thickness of about 450 nm is formed on almost the whole device surface 1a of the wafer 1 by using, for example, low-pressure CVD (chemical vapor deposition). This silicon oxide film is patterned using, for example, typical lithography to convert it into a trench processing hard mask film.

Then, as illustrated in FIG. 6, a trench 5 with a depth of, for example, about 0.8 micrometer (with a width of about 0.15 micrometer) is formed through the trench processing hard mask film by using anisotropic dry etching (using, as an etching atmosphere, a halogen-based gas atmosphere such as HBr).

Next, as illustrated in FIG. 7, a gate oxide film 6 (gate insulating film) with a thickness of, for example, about 30 nm is formed using thermal oxidation or the like.

Next, as illustrated in FIG. 8, a gate polysilicon film 7 (with a thickness of, for example, about 500 nm) is formed using, for example, CVD (chemical vapor deposition) so as to cover almost the entirety on the gate oxide film 6 on the surface 1a side of the semiconductor wafer 1 and bury the trench 5 with the film.

Next, as illustrated in FIG. 9, the gate polysilicon film 7 is etched back by using dry etching with an etching gas such as SF₆, by which a trench gate electrode 7a is formed.

Next, as illustrated in FIG. 10, an interlayer insulating film 8 is formed on almost the whole device surface 1a of the wafer 1 by using, for example, CVD. As a preferred example of the interlayer insulating film 8, a PSG (phosphor-silicate glass) film (with a thickness of, for example, about 300 nm) can be given

Next, as illustrated in FIG. 11, the PSG film outside the trench 5 is removed by planarization treatment such as CMP (chemical mechanical polishing).

Next, as illustrated in FIG. 12, the device surface 1a of the wafer 1 is etched back by about 0.2 micrometer by using dry etching with an etching gas such as SF₆ to make the trench filling members (gate oxide film 6 and interlayer insulating film 8) protrude from the upper portion of the trench 5.

Next, as illustrated in FIG. 13, a P type body region 9 (P type well region or channel region) is introduced using, for example, ion implantation. Preferred examples of the ion implantation condition include: use of boron as an ion species, an implantation energy at about 200 keV, and a concentration at about 7×10¹²/cm².

Next, as illustrated in FIG. 14, a sidewall polysilicon film 34 (at a film formation temperature of, for example, about 580° C.) is formed on almost the whole surface on the surface 1a side of the semiconductor wafer 1 by using, for example, CVD. At this time, it is preferred to use, as the sidewall polysilicon film 34, a phosphorus-doped polysilicon film, that is, a doped polysilicon film (phosphorus concentration of about 4×10²⁰/cm³) from the standpoint of simplifying the process. In some cases, an impurity such as phosphorus may be introduced by ion implantation into a non-doped polysilicon film formed in advance.

Next, as illustrated in FIG. 15, the sidewall polysilicon film 34 is etched back by using, for example, anisotropic dry etching (using, as an etching atmosphere, a halogen-based gas atmosphere such as HBr) to form, as a poly Si source region 11b, a polysilicon sidewall around the trench filling members protruding from the upper portion of the trench 5.

Next, as illustrated in FIG. 16, almost the whole surface of the semiconductor wafer 1 on the surface 1a side is subjected to annealing treatment at about 950° C. for, for example, about 10 minutes to transfer the impurity (phosphorus) in the poly Si source region 11b to the substrate side, by which an N type heavily-doped source region, that is, an N type in-substrate source region 11a is formed. The annealing treatment is conducted preferably, for example, in an atmosphere composed of 1% oxygen and 99% nitrogen (this means, a nitrogen atmosphere or an inert gas atmosphere) under normal pressure. A trace amount of oxygen is added in order to prevent surface roughening of the silicon substrate due to high-temperature heat treatment.

Next, as illustrated in FIG. 17, for example, a P type impurity is ion-implanted into almost the whole surface from the surface 1a side of the semiconductor wafer 1 to introduce, in self alignment, a P type body contact region 14 (P type heavily doped contact impurity region 64) in the surface region of the semiconductor substrate. Preferred examples of the ion implantation condition include: use of BF₂ as an ion species, an implantation energy at about 30 keV, and a concentration at about 1×10¹⁵/cm².

Next, as illustrated in FIG. 18, a TiW film (a large portion of titanium in the TiW film is transferred to the silicon interface, forms silicide, and contributes to improvement in contact properties by the heat treatment conducted later, but these procedures are so cumbersome that they are shown on the drawing) with a thickness of, for example, about 300 nm is formed by using sputtering. Further, an aluminum-based metal film (aluminum added with about several % of silicon or the like) with a thickness of, for example, from about 3 micrometer to 5 micrometer is formed using, for example, sputtering on almost the whole surface on the TiW film on the surface 1a side of the semiconductor wafer 1, similar to the above-described film. This TiW film and the aluminum-based metal film configure an aluminum-based metal electrode film 30. The aluminum-based metal electrode film 30 is then patterned using typical lithography to form a metal source electrode 15, a gate wiring portion 24, a guard ring 27, and the like as illustrated in FIG. 2. If necessary, for example, an organic film (with a thickness of, for example, about 2.5 micrometer) composed mainly of polyimide is applied, as a final passivation film, to almost the whole device surface 1a of the wafer 1. Further, typical lithography is performed to remove the final passivation film from a source pad opening 26 and a gate pad opening 25 as illustrated in FIG. 2.

Next, as illustrated in FIG. 19, the back surface 1b of the wafer 1 is subjected to back grinding treatment to decrease the thickness of the wafer from, for example, about 500 to 900 micrometer to, for example, from about 30 to 300 micrometer.

Next, as illustrated in FIG. 20, a back-surface electrode 4 (for example, titanium film/nickel film/gold film mentioned from the side near the wafer) is formed using sputtering. The wafer 1 is then divided into individual chips 2 (FIG. 2) by dicing or the like.

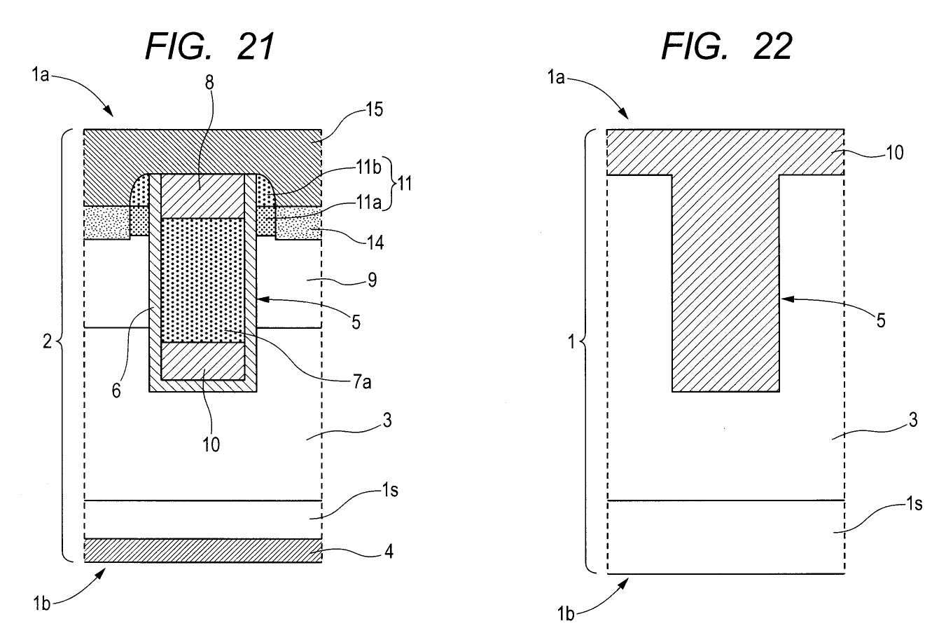

5. Description on Modification Example 1 (thick-film structure of underlying insulating film) of the active cell structure of the power MOSFET which is one example of the semiconductor device according to the one embodiment of the present application (mainly, FIG. 21). The cell structure described in this section is a modification example of the cell structure described in Section 3.

FIG. 21 is a detailed cross-sectional view of an active cell structure (thick-film structure of an underlying insulating film) of a power MOSFET which is one example of a semiconductor device according to the one embodiment (Modification Example 1) of the present application. Based on this drawing, Modification Example 1 of the active cell structure (thick-film structure of an underlying insulating film) of a power MOSFET which is one example of the semiconductor device according to the one embodiment of the present application will be described.

A difference in this cell structure is that compared with that of FIG. 5, the thickness of an insulating film 10 (underlying insulating film of the gate electrode) is greater than the thickness of the gate insulating film 6 alone shown in FIG. 5. The thickness of the insulating film 10 underlying the gate electrode is preferably, for example, about 120 nm. Since in a blocking mode of a trench-gate type power MOSFET, concentration of electric field occurs mainly at the lower end portion of the trench 5, the feedback capacity (capacity between gate and drain) can be reduced by increasing the thickness of the insulating film at this portion. Thus, in the present embodiment, the thickness of the insulating film 10 at the lower end portion of the trench 5 is made greater than that of the gate insulating film 6 contiguous to the P type body region 9.

6. Description on a manufacturing process of Modification Example 1 (thick-film structure of an underlying insulating film) of the active cell structure of the power MOSFET which is one example of the semiconductor device according to the embodiment of the present application (mainly, from FIG. 22 to FIG. 28). In this section, one example of a manufacturing method of the device having the structure of FIG. 5 will be described.

This process is a modification example of the process described in Section 4. The process described in FIG. 6 and from FIG. 12 to FIG. 20 is the same except for the device structure so that only a difference will next be described.

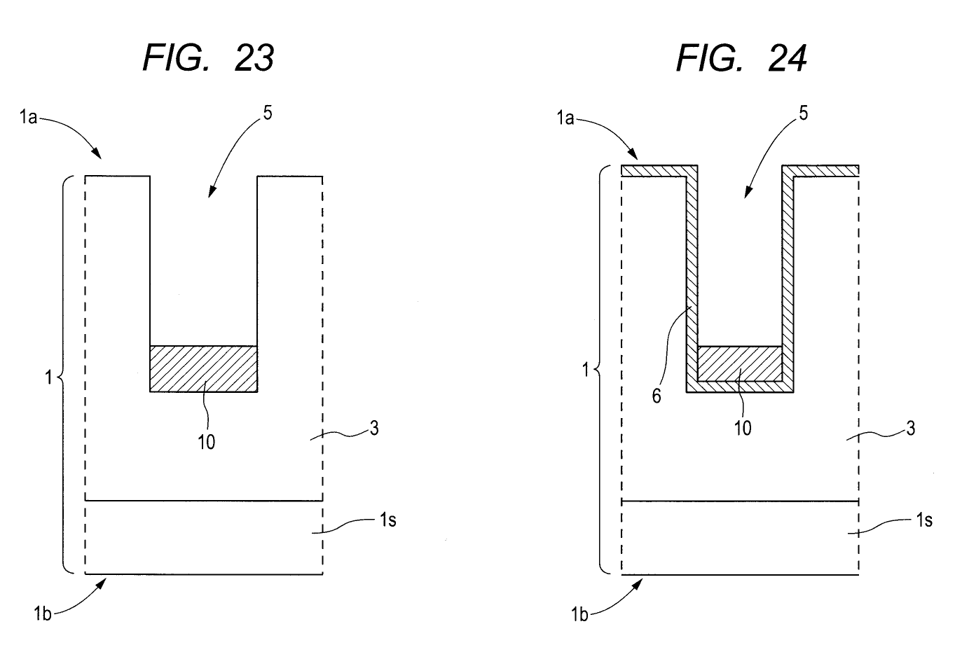

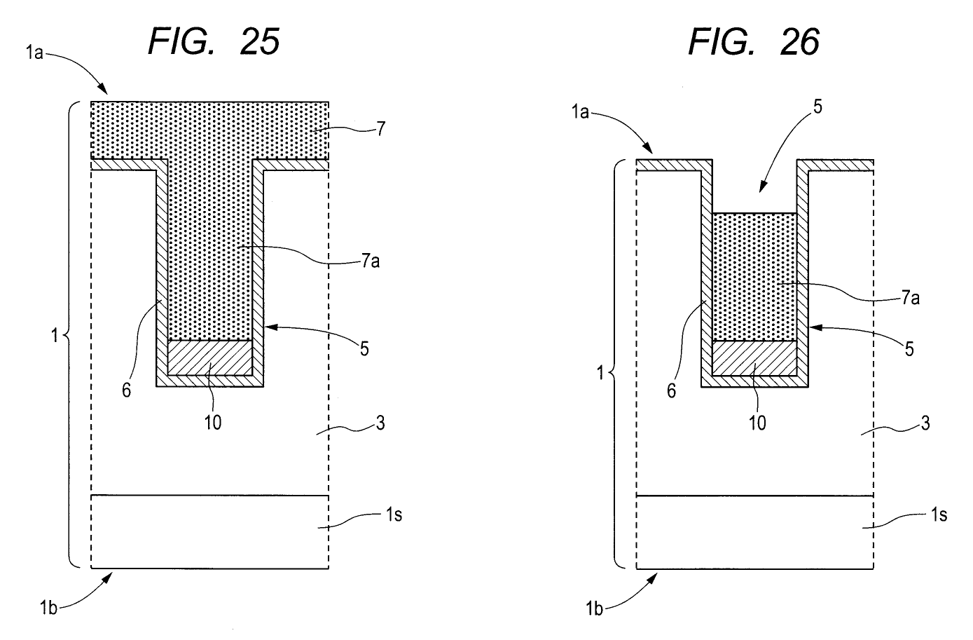

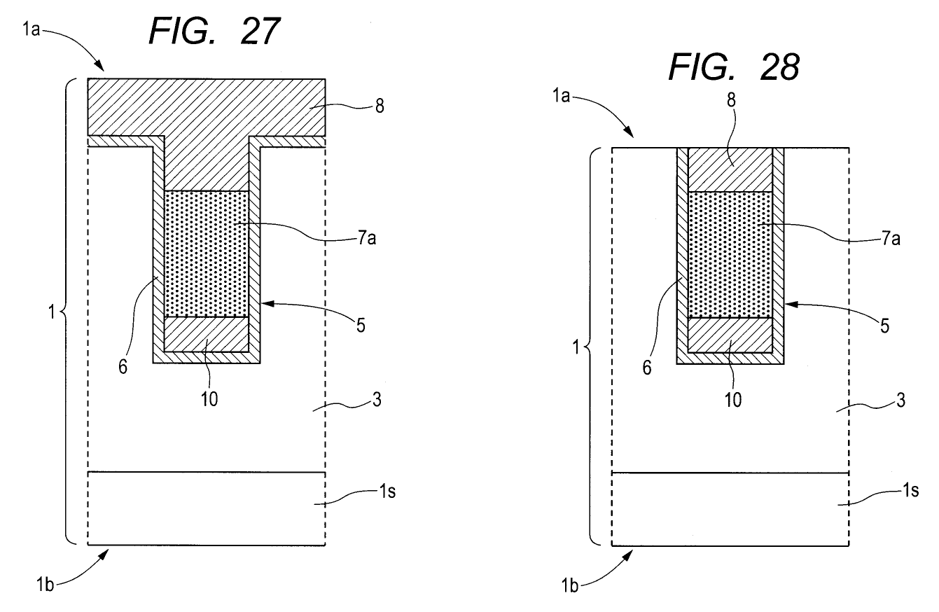

FIG. 22 is a cross-sectional view of the unit cell region corresponding to FIG. 21 (thick-film structure of an underlying insulating film) during a manufacturing step (step of burying an insulating film underlying a gate electrode). FIG. 23 is a cross-sectional view of the unit cell region corresponding to FIG. 21 (thick-film structure of an underlying insulating film) during a manufacturing step (step of etching back the insulating film underlying the gate electrode). FIG. 24 is a cross-sectional view of the unit cell region corresponding to FIG. 21 (thick-film structure of an underlying insulating film) during a manufacturing step (a gate oxidation step). FIG. 25 is a cross-sectional view of the unit cell region corresponding to FIG. 21 (thick-film structure of an underlying insulating film) during a manufacturing step (gate polysilicon burying step). FIG. 26 is a cross-sectional view of the unit cell region corresponding to FIG. 21 (thick-film structure of an underlying insulating film) during a manufacturing step (gate polysilicon etch-back step). FIG. 27 is a cross-sectional view of the unit cell region corresponding to FIG. 21 (thick-film structure of an underlying insulating film) during a manufacturing step (interlayer insulating film burying step). FIG. 28 is a cross-sectional view of the unit cell region corresponding to FIG. 21 (thick-film structure of an underlying insulating film) during a manufacturing step (planarization step). Based on these drawings, the manufacturing process of Modification Example 1 (thick-film structure of an underlying insulating film) of the active cell, structure of the power MOSFET which is one example of the semiconductor device according to the one embodiment of the present application will next be described.

After formation of the structure shown in FIG. 6, an underlying insulating film 10 of a gate electrode is formed on almost the whole device surface 1a of the wafer 1 as illustrated in FIG. 22 so as to bury the trench 5 with the insulating film by using, for example, CVD. As the underlying insulating film 10 of a gate electrode, a silicon oxide-based insulating film (with a thickness of, for example, about 300 nm) can be mentioned as a preferred example.

Next, as illustrated in FIG. 23, the underlying insulating film 10 of a gate electrode is etched back using, for example, a hydrofluoric acid-based wet etching solution to retreat the underlying insulating 10 of a gate electrode into the trench and adjust the thickness to, for example, about 120 nm.

Next, as illustrated in FIG. 24, a gate insulating film 6 with a thickness of, for example, about 30 nm is formed on almost whole device surface 1a of the wafer 1 and the inner surface of the trench 5 by using thermal oxidation or the like.

Next, as illustrated in FIG. 25, a gate polysilicon film 7 is formed on almost the whole device surface 1a of the wafer 1 by using, for example, CVD so as to bury the trench 5 with the film.

Next, as illustrated in FIG. 26, the gate polysilicon film 7 is etched back by using dry etching with an etching gas such as SF₆, by which a trench gate electrode 7a is formed.

Next, as illustrated in FIG. 27, an interlayer insulating film 8 is formed on almost the whole device surface 1a of the wafer 1 by using, for example, CVD. As the interlayer insulating film 8, a PSG film (with a thickness of, for example, about 300 nm) can be given as a preferred example.

Next, as illustrated in FIG. 28, the PSG film outside the trench 5 is removed by planarization treatment such as CMP.

The planarization treatment is followed by the treatment shown in FIG. 12 and then, treatments similar to those in Section 4 are performed.

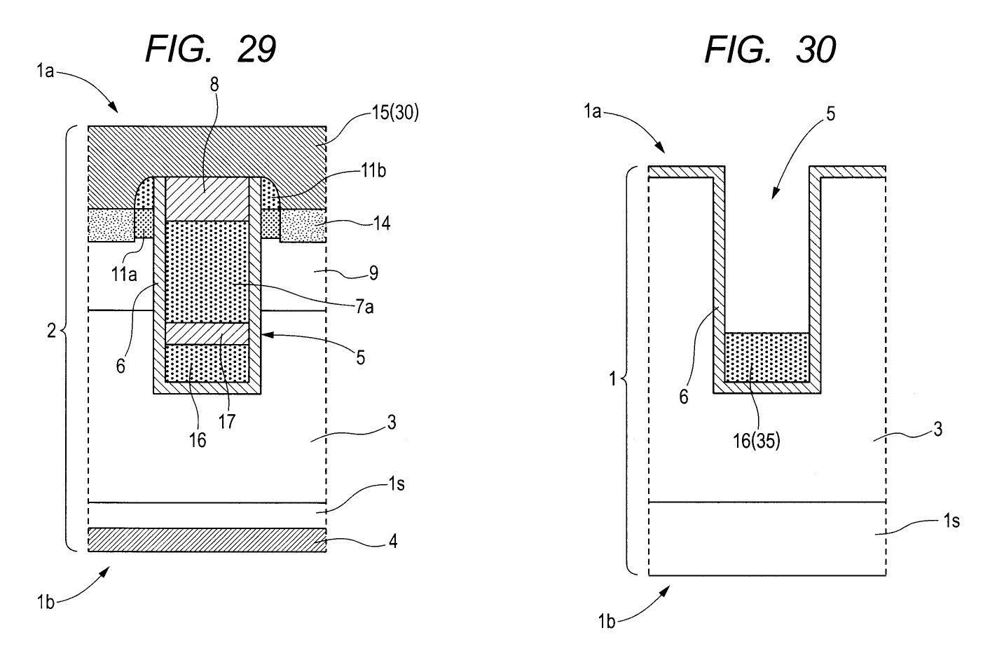

7. Description on Modification Example 2 (dummy gate-added structure) of the active cell structure of the power MOSFET which is one example of the semiconductor device according to the one embodiment of the present application (mainly FIG. 29). FIG. 29 is a detailed cross-sectional view of an active cell structure (dummy gate electrode-added structure) of the power MOSFET which is one example of the semiconductor device according to the one embodiment (Modification Example 2) of the present application. Based on this drawing, Modification Example 2 (dummy gate-added structure) of the active cell structure of the power MOSFET which is one example of the semiconductor device according to the one embodiment of the present application will be described.

The characteristic in this example is that, as illustrated in FIG. 29, a buried field plate set at a source potential (usually coupled to the source electrode 15 outside the trench 5 and set at a substantially equal potential to that of the source electrode 15), that is, a dummy gate 16 is provided below the trench gate electrode 7a in the trench 5. This structure is advantageous because even if the concentration of the N-drift region 3 is set high, a necessary withstand voltage can be secured and an On-state resistance can be reduced. In addition, a feedback capacity (capacity between gate and drain) can be reduced. The potential of the dummy gate 16 may be set at a gate potential but in this case, the capacity between gate and source and the capacity between gate and drain show a relative increase.

8. Description on the manufacturing process of Modification Example 2 (dummy-gate added structure) of the active cell of the power MOSFET which is one example of the semiconductor device according to the one embodiment of the present application (mainly from FIG. 30 to FIG. 35). In this section, one example of the manufacturing method of a device having the structure of Section 7 will be described.

This process is a modification example of the process described in Section 4 and they are the same in from FIG. 6 to FIG. 8 and FIG. 12 to FIG. 20 except for the device structure. Therefore, only a difference will next be described.

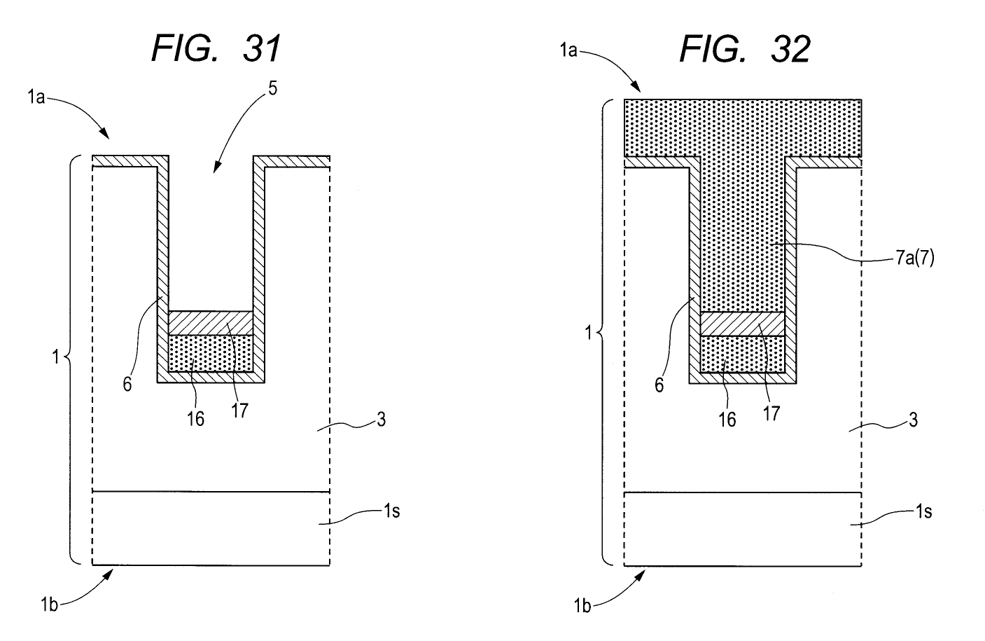

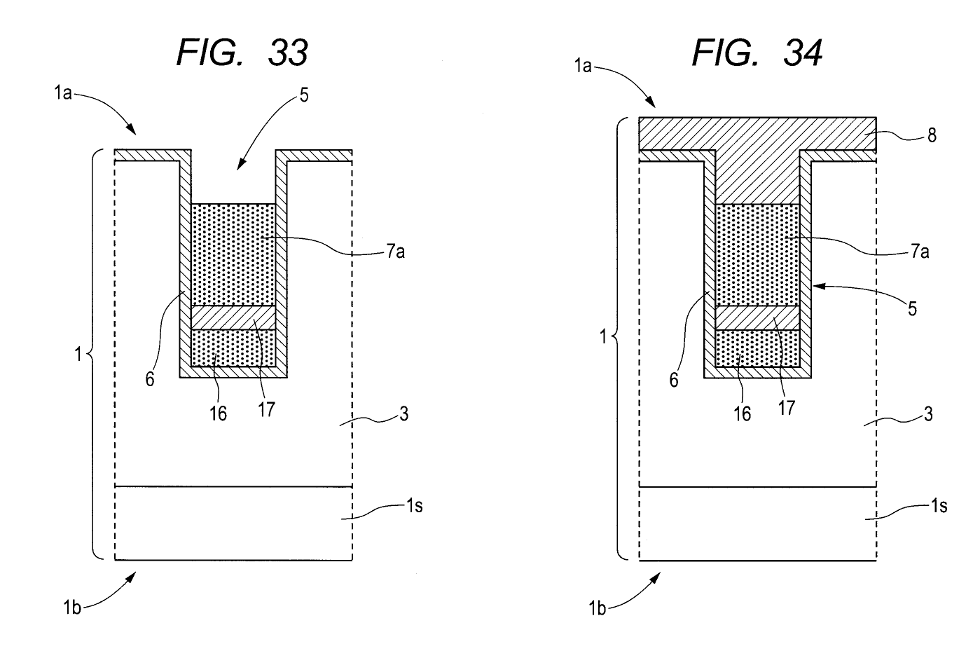

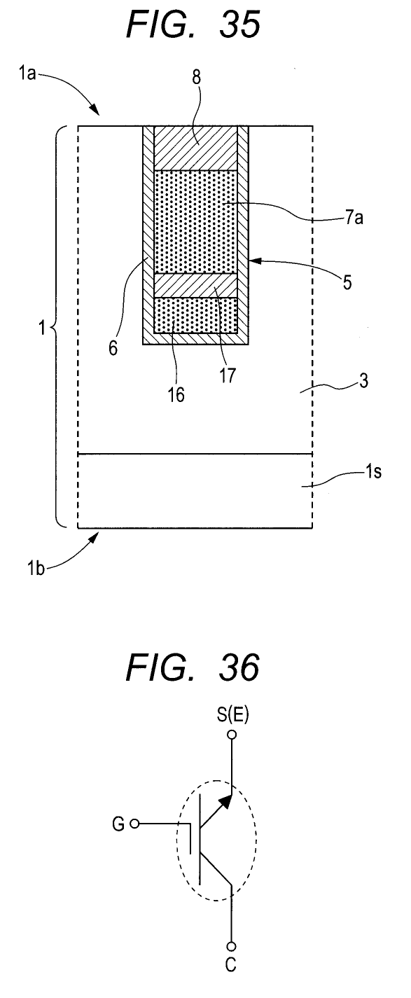

FIG. 30 is a cross-sectional view of the unit cell region corresponding to FIG. 29 (dummy gate electrode-added structure) during a manufacturing step (dummy gate polysilicon etch-back step). FIG. 31 is a cross-sectional view of the unit cell region corresponding to FIG. 29 (dummy gate electrode-added structure) during a manufacturing step (step of forming an insulating film crossing a trench gate). FIG. 32 is a cross-sectional view of the unit cell region corresponding to FIG. 29 (dummy gate electrode-added structure) during a manufacturing step (gate polysilicon burying step). FIG. 33 is a cross-sectional view of the unit cell region corresponding to FIG. 29 (dummy gate electrode-added structure) during a manufacturing step (gate polysilicon etch-back step). FIG. 34 is a cross-sectional view of the unit cell region corresponding to FIG. 29 (dummy gate electrode-added structure) during a manufacturing step (interlayer insulating film burying step). FIG. 35 is a cross-sectional view of the unit cell region corresponding to FIG. 29 (dummy gate electrode-added structure) during a manufacturing step (planarization step). Based on these drawings, the manufacturing process of Modification Example 2 (dummy gate-added structure) of the active cell structure of the power MOSFET which is one example of the semiconductor device according to the one embodiment of the present application will be described.

In the state of FIG. 8 (the polysilicon film is not the gate polysilicon film 7 but a polysilicon film 35 for dummy gate electrode formed under almost the same film formation conditions), the polysilicon film 35 for dummy gate electrode is etched back by using dry etching with an etching gas such as SF₆ as illustrated in FIG. 30, By this etching, a dummy trench gate electrode 16 (buried field plate) is formed.

Next, as illustrated in FIG. 31, a silicon oxide film of about 100 nm, that is, an insulating film 17 crossing a trench gate is formed on the upper surface of the dummy trench gate electrode 16 by using, for example, thermal oxidation.

Next, as illustrated in FIG. 32, a gate polysilicon film 7 (with a thickness of, for example, about 500 nm) is formed using, for example, CVD so as to cover almost the entirety on the gate oxide film 6 and the insulating film 17 crossing a trench gate on the surface 1a side of the semiconductor wafer 1 and bury the trench 5 with the film.

Next, as illustrated in FIG. 33, the gate polysilicon film 7 is etched back by using dry etching with an etching gas such as SF₆, by which a trench gate electrode 7a is formed.

Next, as illustrated in FIG. 34, an interlayer insulating film 8 is formed on almost the whole device surface 1a of the wafer 1 by using, for example, CVD. As the interlayer insulating film 8, for example, a PSG film (with a thickness of, for example, about 300 nm) can be given as a preferred example.

Next, as illustrated in FIG. 35, the PSG film outside the trench 5 is removed by planarization treatment such as CMP.

The planarization treatment is followed the treatment shown in FIG. 12 and then, treatments similar to, those in Section 4 are performed.

9. Description on application, to another active device, of the embodiments described in the present application (mainly from FIG. 36 to FIG. 39). A specific description has so far been made with a power MOSFET as a main example. It is needless to say that the concept of the embodiments described herein can also be applied to insulating gate-type power active elements as a whole. Examples of the insulating gate-type power active elements include, in addition to power MOSFET, IGBT (insulated gate bipolar transistor) and integrated power devices obtained by integrating, on a single chip, an insulating gate-type power active element and a CMOS (complementary metal oxide semiconductor), a CMIS (complementary metal insulator semiconductor) integrated circuit, or the like. These elements or devices will next be described briefly.

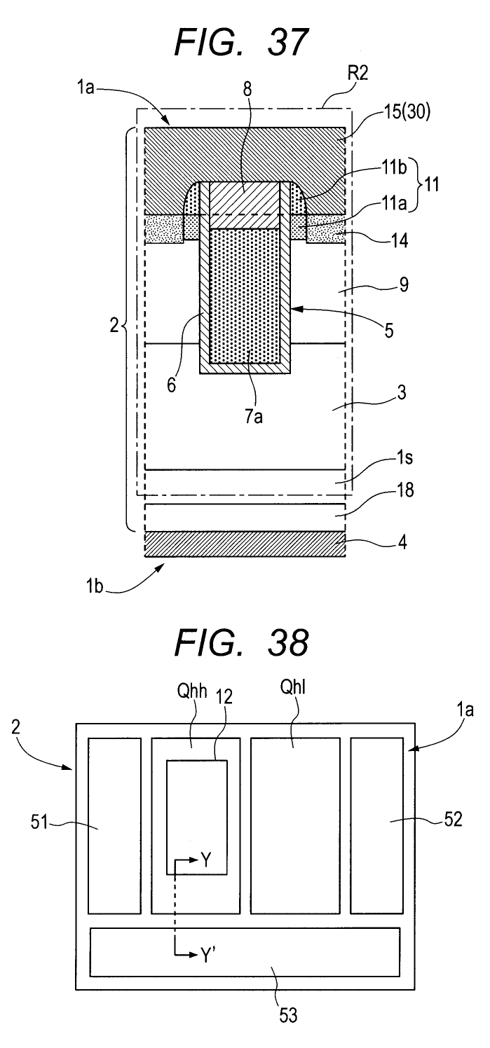

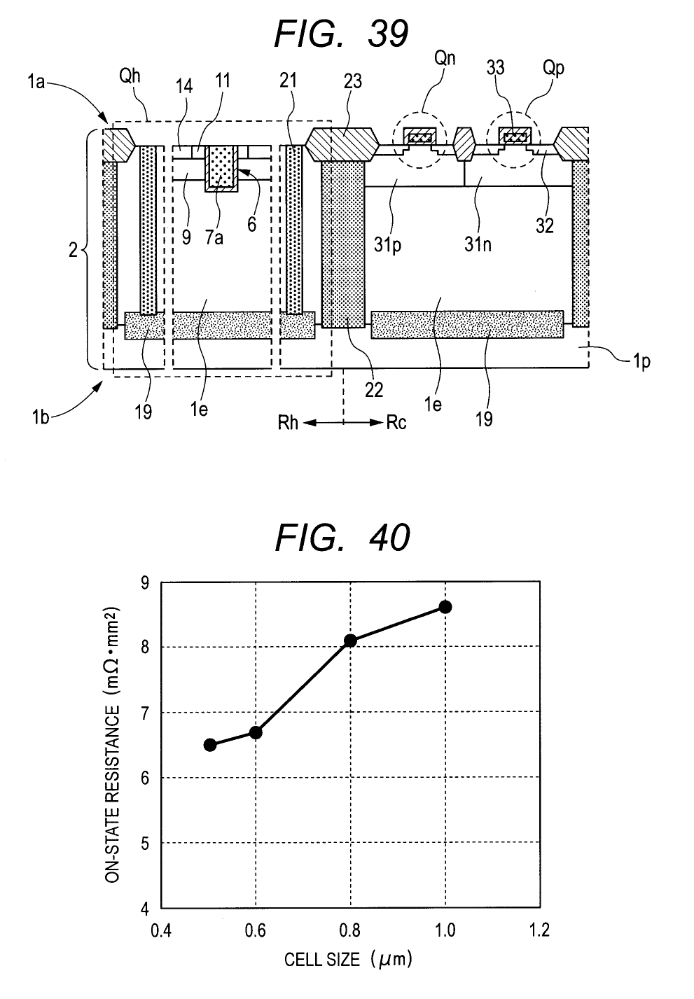

FIG. 36 shows a layout of terminals of IGBT which is one example of another active device to which the embodiment described herein can be applied. FIG. 37 is a cross-sectional view of a unit cell of the IGBT, corresponding to FIG. 5, which is one example of another active device to which the embodiment described herein can be applied. FIG. 38 is a top layout of a single chip of an integrated power-source element on which a major portion of the circuit elements in FIG. 1 have been integrated. FIG. 39 is a fragmentary schematic cross-sectional view of a chip corresponding to the Y-Y′ cross-section of FIG. 38. Based on these drawings, application of the embodiments described herein to another active device will next be described.

(1) Application to IGBT (mainly, FIGS. 36 and 37): As illustrated in FIG. 36, because of the relationship with pins of a bipolar transistor, each terminal of IGBT is usually called as follows in accordance with a circuit-related naming. A terminal corresponding to a base is called a gate terminal G, a terminal corresponding to an emitter is called an emitter terminal, and a terminal corresponding to a collector is called a collector terminal C. From the standpoints of structure and operation, however, it is natural to call the emitter terminal E a source terminal.

Described specifically, as illustrated in FIG. 37, IGBT has such a structure that a P type collector region 18 is inserted between a back-surface metal electrode 4 (collector electrode) and the back surface 1b side of an N type semiconductor substrate region 1s of R2 which is a structurally equal portion to the power MOSFET described in FIG. 5. In accordance with the structural naming, the source-related portions can therefore be called as are such as source region 11, N type in-substrate source region 11a, poly Si source region 11b, metal source electrode 15, source pad portion 26, source contact portion 29a, and the like. The gate-related portions can of course be called as are because they correspond to those of the power MOSFET.

(2) Application to a device obtained by integrating power-type active element and the like (mainly, FIGS. 38 and 39) FIG. 38 shows one example of a top layout of a chip 2 of a one-chip type DC-DC converter (corresponding to FIG. 1) for personal computer which is one example of the integrated power-type device. As illustrated in FIG. 38, a high side SW power MOSFET (Qhh), a low side SW power MOSFET (Qhl), a high side driver 51 for driving the high side SW power MOSFET (Qhh), a low side driver 52 for driving the low side SW power MOSFET (Qhl), and a control circuit portion 53 for controlling the high side driver 51 and the low side driver 52 (for example, circuit has a CMOS circuit configuration) are laid out on the device surface 1a of the chip 2. The high side SW power MOSFET (Qhh) described herein is, more specifically, any of the power active elements (insulating-gate type power active elements) described in FIGS. 5, 21, 29, and 37. The low side SW power MOSFET (Qhl) can also have any of such configurations.

Next, fragmentary cross-section (Y-Y′ cross-section) of an active region 12 and a CMOS control circuit portion 53 of the high side SW power MOSFET (Qhh) will be described referring to FIG. 39. In order to prevent the drawing from becoming complicated, however, the conventional basic structure is shown as the portions of the power MOSFET Qh corresponding to the high side SW power MOSFET (Qhh) or low side SW power MOSFET (Qhl).

As illustrated in FIG. 39, a one-chip type DC-DC converter is fabricated on, for example, a P type semiconductor substrate 1p. Described specifically, on the side of a surface 1a (first main surface or device surface) of the P type semiconductor substrate 1p (P type semiconductor substrate region), for example, an N-epitaxial region le formed using epitaxial growth or the like is provided. An N+ type buried region 19 is provided near the boundary between this N-epitaxial region 1e and the P type semiconductor substrate region 1p. In the N-epitaxial region 1e between a CMOS region Rc and a power MOS region Rh, a P+ element isolation region 22 is provided. On the upper surface 1a of the chip 2 on the P+ element isolation region, a field insulating film 23 (LOCOS or STI type insulating film) is provided.

Next, each device region will be described. In a region where a power MOS region Rh, that is, a power MOSFET (Qh) has been formed, an N+ drain lead-out region 21 for leading out a drain or the like to the upper surface 1a of the chip 2 is provided and in a semiconductor surface region on the upper surface 1a of the chip 2, a trench 5, a gate insulating film 6, a P type body region 9, a source region 11, and a P type body contact region 14, and the like are provided.

In the CMOS region Rc, on the other hand, a P well region 31p and an N well region 31n are provided below the surface of the chip 2 in the N-epitaxial region 1e on the upper surface 1a side. These surface regions are provided with N type and P type source drain regions 32. Further, the chip 2 has, on the top surface 1a thereof, a gate electrode 33 configuring an N-channel MOSFET (Qn) and a P channel MOSFET (Qp) together with these N type and P type source drain regions 32.

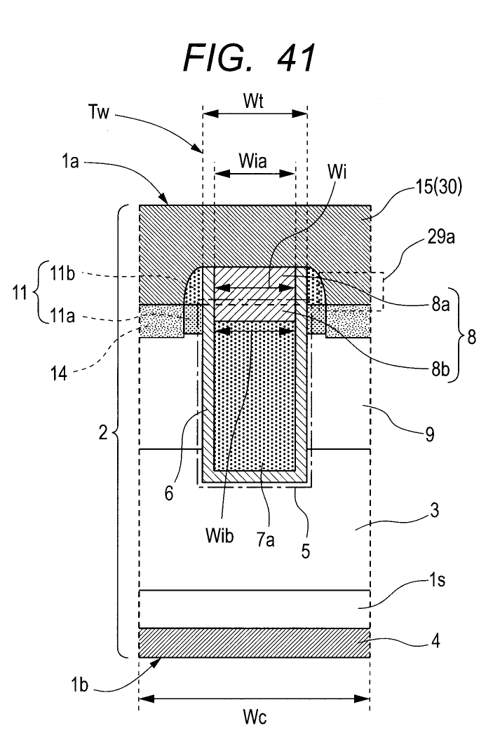

10. Consideration on the present application in general and complementary description on each embodiment (mainly, FIGS. 40 and 41) FIG. 40 is a data plotted diagram showing the relationship, in a trench-gate vertical-channel type power MOSFET, between cell size and on-state resistance. Based on this diagram and the other diagrams, consideration on the present application in general and complementary description on each embodiment will next be performed. FIG. 41 is a cross-sectional view of a unit cell corresponding to FIG. 5 for explaining the relationship among elements around a trench in each embodiment of the present application.

When a low-voltage large-current output is taken into consideration, one of the most important parameters as conditions required for a high side switch is presumed to be a low on-state resistance. With regard to this, as shown in FIG. 40, it has been elucidated that on-state resistance can be reduced efficiently by miniaturizing a cell size. In the conventional cell structure, however, there is a limit in miniaturization. This means that fine-line lithography requiring alignment is employed in patterning of an interlayer insulating film, introduction of a source region, formation of a contact hole, and the like so that miniaturization to a cell size of around 0.4 micrometer (further, a cell size less than this size) is difficult in consideration of an error in lithography. In the embodiments according to the present application, the cell structure and a manufacturing method thereof are designed to omit a patterning step that needs fine-line lithography, that is, fine alignment (requiring alignment accuracy as strict as the positional accuracy of an element in the cell) during steps after trench formation until metal-electrode patterning. Even if the fine-line lithography is not employed, however, using of lithography for areas which are not fine (large areas compared with members to be formed, for example, pattern regions such as field ring outside the active region to be formed simultaneously) is not excluded.

Details of them will next be described referring to FIG. 41 (cell structure corresponding to FIG. 5). As illustrated in FIG. 41, the width of an interlayer insulating film 9 is defined by burying a trench 5 therewith and it is formed in self alignment with the trench 5. Of a source region 11, a poly Si source region 11b (sidewall) is formed in self alignment with trench filling members as a sidewall of them. On the other hand, of the source region 11, when an N type in-substrate source region 11a is made of an impurity from a doped polysilicon (poly Si source region 11b) or when it is formed via the poly Si source region 11b by ion implantation, it is formed in self alignment with the poly Si source region 11b. Further, a contact hole 29 is formed in self alignment through the formation of the sidewall (poly Si source region 11b).

Thus, according to each embodiment of the present application, the lithography is conducted only for trench patterning and the width Wi (width at the center portion) of the interlayer insulating film is determined only by the width Wt of the trench and the thickness of the gate insulating film. Accordingly, the width Wt of the trench 5 and the width Wi of the interlayer insulating film 8 are almost equal (to be precise, the width Wi of the interlayer insulating film is smaller by the thickness of the gate insulating film on both sides at the portion).

In addition, the interlayer insulating film 8 is confined in the trench 5 (as a final structure, confined as a portion of the trench filling member) from the standpoint of the formation process so that the width Wia at the upper portion 8a of the interlayer insulating film 8 and the width Wib at the lower portion 8b of the interlayer insulating film are inevitably almost the same. Incidentally, the final structure is that an upper portion 8a of the interlayer insulating film 8 protrudes from the upper end of the trench 5 and the lower portion 8b of the interlayer insulating film 8 is housed in the trench 5.

Further, the poly Si source region 11b and the N type in-substrate source region 11a are provided in contact with each other and almost perpendicularly along the side surface (refer to a flat surface Tw corresponding to the sidewall of the trench) of the trench 5 having almost a flat surface. The width of the source region 11 is therefore determined only by the process so that it is basically free from the error of lithography.

The width of the P type body contact region 14 is determined in self alignment as a remaining portion of the peripheral structure of the trench filling members comprised of the trench 5 and the sidewall thereof so that the width of the cell (meaning cell size and is herein, for example, about 0.4 micrometer) can be determined with a high degree of accuracy.

Thus, the structure or manufacturing method of each embodiment makes it possible to form a markedly minute trench-type cell because a cell size can be determined almost only by patterning accuracy.

11. Summary: Thus, the inventions made by the present inventors were described specifically based on some embodiments. It should however be borne in mind that the invention is not limited to them but can be changed without departing from the gist of the invention.

For example, in the above-described embodiments, an N-channel device formed mainly on the upper surface of an N-epitaxial layer on an N+ silicon single crystal substrate was described specifically. The present invention is however not limited to it but can also be applied to a P channel device formed on the upper surface of an N epitaxial layer on a P+ silicon single crystal substrate.

In addition, in the above-described embodiments, a power MOSFET was described specifically as an example. The invention is not limited to it but, needless to say, it can also be applied to bipolar transistors (including IGBT). It is needless to say that the invention can also be applied to semiconductor integrated circuit devices and the like incorporating such a power MOSEFT or bipolar transistor therein.

In the above-described embodiments, a device fabricated on a silicon-based semiconductor substrate was mainly described. The invention is not limited to it but can also be applied almost as it to devices fabricated on a GaAs-based semiconductor substrate, a silicon carbide-based semiconductor substrate, or a silicon nitride-based semiconductor substrate.

In the above-described embodiments, as a gate electrode, that using a polysilicon film was described mainly and specifically. The invention is not limited to it and needless to say, a gate electrode may be made of a polycide film or silicide film.

In the above-described embodiments, as a metal electrode, that using an aluminum-based metal film as a main constituent film was described mainly and specifically. The invention is not limited to it and needless to say, it can be applied to a metal electrode using a refractory metal film such as titanium or tungsten or a gold film as a main constituent film.

Further, in the above-described embodiments, as a drift region, that comprised of a single conductivity type region was described specifically. The invention is not limited to it and needless to say, it can also be applied to a super-junction type drift region in which regions having conductivity types opposite to each other appear alternately.

What is claimed is:

1. A semiconductor device comprising:
(a) a semiconductor substrate having a first main surface and a second main surface;
(b) a first-conductivity type drift region provided in the semiconductor substrate;
(c) an active region provided over the first main surface; and
(d) many unit cell regions provided in the active region when viewed planarly,
the unit cell regions each penetrating through the drift region from the upper portion of the first main surface and comprising:
(d1) a body region provided in the semiconductor substrate on the first main surface side in the drift region and having a second conductivity type, which is a conductivity type opposite to the first conductivity type;
(d2) a trench provided in the first main surface of the semiconductor substrate and penetrating through the body region to reach the drift region;
(d3) a gate electrode provided in the trench via a gate insulating film;
(d4) an interlayer insulating film provided over the gate electrode;
(d5) a first-conductivity type in-substrate source region provided in the surface of the semiconductor substrate on the first main surface side but outside the trench so as to come into contact with the gate insulating film;
(d6) a poly Si source region provided on both sides of the interlayer insulating film so as to come into contact with an upper portion of the in-substrate source region; and
(d7) a metal source electrode provided over the first main surface of the semiconductor substrate so as to cover the interlayer insulating film and the poly Si source region,
wherein the width of the interlayer insulating film and the width of the trench are substantially equal.

2. The semiconductor device according to claim 1, wherein the gate electrode is a polysilicon electrode.

3. The semiconductor device according to claim 2, wherein the poly Si source region is a sidewall of the interlayer insulating film.

4. The semiconductor device according to claim 3, wherein an impurity having the same conductivity type as that of the in-substrate source region has been doped in the poly Si source region.

5. The semiconductor device according to claim 4, wherein the drift region is an N-type epitaxy region.

6. The semiconductor device according to claim 5, wherein an N type drain region is provided on the second main surface side of the semiconductor substrate.

7. The semiconductor device according to claim 6, wherein the thickness of the gate insulating film at the lower end of the trench is greater than the thickness of a portion of the gate insulating film contiguous to the body region.

8. The semiconductor device according to claim 6, wherein a dummy gate electrode is provided below the gate electrode and at the lower end portion of the trench via the gate insulating film.

9. The semiconductor device according to claim 8, wherein the dummy gate electrode is a polysilicon dummy gate electrode.

10. The semiconductor device according to claim 9, wherein the dummy gate electrode is adjusted to have a potential substantially equal to the potential of the metal source electrode.

11. A semiconductor device comprising:
(a) a semiconductor substrate having a first main surface and a second main surface;
(b) a first-conductivity type drift region provided in the semiconductor substrate;
(c) an active region provided over the first main surface; and
(d) many unit cell regions provided in the active region when viewed planarly,
the unit cell regions each penetrating through the drift region from the upper portion of the first main surface and comprising:
(d1) a body region provided in the semiconductor substrate on the first main surface side in the drift region and having a second conductivity type, which is a conductivity type opposite to the first conductivity type;
(d2) a trench provided in the first main surface of the semiconductor substrate and penetrating through the body region to reach the drift region;
(d3) a gate electrode provided in the trench via a gate insulating film;
(d4) an interlayer insulating film provided over the gate electrode;
(d5) a first-conductivity type in-substrate source region provided in the surface of the semiconductor substrate on the first main surface side but outside the trench so as to come into contact with the gate insulating film;
(d6) a poly Si source region provided on both sides of the interlayer insulating film so as to come into contact with an upper portion of the in-substrate source region; and
(d7) a metal source electrode provided over the first main surface of the semiconductor substrate so as to cover the interlayer insulating film and the poly Si source region,
wherein the in-substrate source region and the poly Si source region are provided along a substantially flat sidewall of the trench.

12. The semiconductor device according to claim 11,
wherein the gate electrode is a polysilicon electrode.

13. The semiconductor device according to claim 12,
wherein the poly. Si source region is a sidewall of the interlayer insulating film.

14. The semiconductor device according to claim 13,
wherein an impurity having the same conductivity type as that of the in-substrate source region has been doped in the poly Si source region.

15. The semiconductor device according to claim 14,
wherein the drift region is an N-type epitaxy region.

16. The semiconductor device according to claim 15,
wherein an N type drain region is provided on the second main surface side of the semiconductor substrate.

17. The semiconductor device according to claim 16,
wherein the thickness of the gate insulating film at the lower end of the trench is greater than the thickness of a portion of the gate insulating film contiguous to the body region.

18. The semiconductor device according to claim 16,
wherein a dummy gate electrode is provided below the gate electrode and at the lower end portion of the trench via the gate insulating film.

19. The semiconductor device according to claim 18,
wherein the dummy gate electrode is a polysilicon dummy gate electrode.

20. The semiconductor device according to claim 19,
wherein the dummy gate electrode is adjusted to have a potential substantially equal to the potential of the metal source electrode.
